(19) United States
(12) Patent Application Publication
(10) Pub. No.: US 2013/0020113 A1
(43) Pub. Date: Jan. 24, 2013

(54) Nanoparticle Electrodes and Methods of Preparation

(71) Applicants: Javier Jesus Concepcion Corbea, Chapel Hill, NC (US); Jonah Wesley Jurss, Berkeley, CA (US); Paul Hoertz, Morrisville, NC (US); Thomas J. Meyer, Chapel Hill, NC (US)

(72) Inventors: Javier Jesus Concepcion Corbea, Chapel Hill, NC (US); Jonah Wesley Jurss, Berkeley, CA (US); Paul Hoertz, Morrisville, NC (US); Thomas J. Meyer, Chapel Hill, NC (US)

(21) Appl. No.: 13/575,422

(22) PCT Filed: Jan. 21, 2011
(86) PCT No.: PCT/US11/21978

§ 371 Date: Sep. 17, 2012

Related U.S. Application Data
(60) Provisional application No. 61/298,825, filed on Jan. 27, 2010.
(60) Provisional application No. 61/298,560, filed on Jan. 27, 2010.

(51) Int. Cl. H05K 1/09; B82Y 99/00

(52) U.S. Cl. 174/257; 977/773; 977/932

(57) ABSTRACT

The present invention provides an electrode which comprises (a) a supporting substrate, and (b) nanoparticle composition comprising optically transparent conductive nanoparticles. In one embodiment, the nanoparticles are selected from tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide and aluminum zinc oxide (AZO) nanoparticles and combinations thereof. In one embodiment, the electrode further comprises a transition metal catalyst, and the catalyst is absorbed to the surface of the nanoparticles. Another aspect of the invention relates to methods for preparing the electrode described herein which comprises the step of (1) preparing a suspension of nanoparticles; (2) applying the suspension of the nanoparticles to a support substrate; and (3) annealing the supporting substrate with the nanoparticle for a period of time and at a temperature sufficient to produce nanoparticle film on the electrode.

### RELATED APPLICATIONS

This application claims the benefit under 35 §119(e) of U.S. Provisional Patent Application Ser. No. 61/298,560, filed Jan. 27, 2010 and 61/298,825, filed Jan. 27, 2010, the disclosures of which are incorporated herein by reference in their entirety.

### GOVERNMENT SUPPORT

This invention was made with government support under grant number DE-FG09-06ER15788 awarded by the Department of Energy, Grant No. W911NF-09-1-0426 awarded by Army Research Office, and DE-SC0001011 awarded by UNC EFRC: Solar Fuels and Next Generation Photovoltaics, an Energy Frontier Research Center funded by U.S. DOEBES. The government has certain rights in this invention.

### FIELD OF THE INVENTION

The present invention generally relates to electrodes which comprise nanoparticle composition. The electrodes described herein may be used in broad applications.

### BACKGROUND OF THE INVENTION

Conventionally, electrode materials having high transmittance of visible light have been used to prepare various electrodes of display devices such as liquid crystal display devices, plasma display panels, electroluminescence display devices, etc. Exemplary transparent conductive materials include indium tin oxide (ITO), fluorine doped tin oxide (FTO), and antimony-doped tin oxide (ATO), etc. The ITO having a low specific resistance and therefore it has been widely used.

Since 1991, surface-derivatized semiconducting nanoparticles in a thin film configuration have been used for dye-sensitized solar cells (DSSCs). For example, the underivatized transparent TiO₂ nanoparticle films may offer effective surface areas about one thousand times higher than those of planar surfaces. The TiO₂ nanoparticle films are highly porous, which permit diffusion of solvent and electrolyte throughout the film. It has been reported that conductive, porous nanoparticle films of metals such as Au have been prepared, but they are highly absorbing even at thicknesses<100 nm.

However, little research has been conducted in the area of nanoparticle electrodes using transparent conductive material.

### SUMMARY OF THE INVENTION

The present invention provides electrodes which comprise (a) a supporting substrate and (b) nanoparticle composition comprising optically transparent conductive nanoparticles on the supporting substrate. In one embodiment, the nanoparticles are selected from the group consisting of tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide and aluminum zinc oxide (AZO) nanoparticles and a combination thereof. In one embodiment, the electrode is used for electrolysis of water molecules. In another embodiment, the electrode is used for photo-electrolysis of water molecules. In one embodiment, the electrode further comprises at least one transition metal catalyst, and the catalyst is on the surface of the nanoparticles. In one embodiment, the electrode further comprises at least one dye compound.

Another aspect of the invention relates to methods for preparing the electrode described herein comprise the step of (1) preparing a suspension of nanoparticles; (2) applying the suspension of the nanoparticles to a support substrate; and (3) annealing the supporting substrate with the nanoparticles for a period of time and at a temperature sufficient to produce a nanoparticle film on the electrode.

Further aspect of the invention provides electrochemical cells for electrolysis of water molecules comprising a container and at least one electrode described herein in said container. Another aspect of the invention provides solar cells comprising at least one electrode described herein. Further, one aspect of the invention provides light-emitting devices or light-emitting diodes which comprise at least one electrode described herein. One aspect of the invention provides electrochromic devices which comprise at least one electrode comprising a transparent or translucent substrate coated with a nanoparticle composition selected from the group consisting of tin-doped indium oxide (ITO), fluorine doped tin oxide (FTO), antimony tin oxide (ATO), gallium zinc oxide (GZO), indium zinc oxide (IZO), copper aluminum oxide, aluminum zinc oxide (AZO), and fluorine-doped zinc oxide nanoparticles and combinations thereof. One aspect of the invention provides energy storage devices or capacitors, which comprise at least one layer comprising nanoparticle composition selected from the group consisting of tin-doped indium oxide (ITO), fluorine doped tin oxide (FTO), antimony tin oxide (ATO), fluorine-doped zinc oxide, gallium zinc oxide (GZO), indium zinc oxide (IZO), copper aluminum oxide, and aluminum zinc oxide (AZO) nanoparticles and combinations thereof. A further aspect of the invention provides spectrophotometric monitoring devices comprising at least one electrode described herein.

Objects of the present invention will be appreciated by those of ordinary skill in the art from a reading of the Figures and the detailed description of the preferred embodiments which follow, such description being merely illustrative of the present invention.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1 demonstrates top-down (left) and cross-sectional (right) field emission scanning electron microscopy (FESEM) images of a nanoITO/ITO slide (2.5 μm) following annealing at 500° C. under atmospheric conditions and after 3% H₂/N₂ annealing at 300° C. For both images, a thin coating of Au/Pd was deposited prior to imaging.

FIG. 2 shows the correlation of film thicknesses as determined by profilometry for nanoITO films prepared by spin-coating suspensions with varying NanoITO concentrations onto planar substrates.

FIG. 3 shows UV-visible-near IR spectra of oxidized (red line) and reduced (blue line) ITO|nanoITO. Film thickness, ˜2.5 μm.

FIG. 4(a) shows UV-vis spectra of ITO|nanoITO after various soaking times in 0.1 mM [Ru(bpy)₂(4,4′-PO₃H₂-bpy)]²⁺ solution in methanol. FIG. 4 (b) demonstrates dependence of the absorbance at 453 nm on the soaking time. Film thickness, ˜2.5 μm. Γₒ=2.5×10⁻⁸ mol/cm².

FIG. 5 demonstrates adsorption isotherm for [Ru(bpy)₂(4,4′-PO₃H₂-bpy)]²⁺ on ITO|nanoITO after soaking in methanol stock solution for 72 h at 25° C. Thickness, ˜2.5 μm, Γₒ=2.5×10⁻⁸ mol/cm².

FIG. 6(a) graphically demonstrates cyclic voltammograms (CVs) of ITO|nanoITO-Ru(bpy)₂(4,4′-PO₃H₂-bpy)]²⁺(ITO|nanoITO-Ru^{II}): in aqueous 0.1 M HClO₄. FIG. 6(b) shows cyclic voltammograms (CVs) of ITO|nanoITO-Ru(bpy)₂(4,4′-PO₃H₂-bpy)]²⁺(ITO|nanoITO-Ru^{II}) in 0.1 MⁿBu₄NPF₆/MeCN (deaerated). Thickness, 2.5 μm; scan rate, 10 mV/s. The dotted lines are ITO|nanoITO backgrounds.

FIG. 7 demonstrates cyclic voltammograms (CVs) of blank nanoTiO₂ in 0.1 M ⁿBu₄NPF₆/MeCN. Scan rate, 10 mV/s. Electrolyte solution was degassed.

FIG. 8 demonstrates dependence of the peak current of the Ru(III/II) redox couple at ITO|nanoITO-Ru^{II} on the scan rate. Film thickness, ˜2.5 μm; electrolyte solution, aqueous 0.1 M HClO₄.

FIG. 9 (a) shows cyclic voltammograms for ITO|nanoITO-Ru^{II} recorded at various scan rates and film thicknesses in 0.1 M ⁿBu₄NPF₆/MeCN. FIG. 9 (b) demonstrates peak-to-peak splittings (ΔE_{P}=E_{p,a}−E_{p,c}) as a function of scan rate and film thickness.

FIG. 10 (a) shows cyclic voltammograms for underivatized, ˜2.5 μm ITO|nanoITO recorded in 0.1 M HClO₄/H₂O. FIG. 10 (b) shows cyclic voltammograms for underivatized, ˜2.5 μm ITO|nanaITO recorded in 0.1 M ⁿBu₄NPF₆/MeCN at different scan rates. FIG. 10(c) shows non-faradaic currents at 1.3 V vs. NHE for underivatized ITO|nanoITO: 0.55 μm (black line), 2.5 μm (red line), and 6.7 μm (green line) in 0.1 M ⁿBu₄NPF₆/MeCN.

FIG. 11 (a) demonstrates UV-visible spectra of ITO|nanoITO-Ru^{II} (2.5 μm) at an applied potential of 0.55 V vs. NHE (red line) and at 1.55 V (blue line) in 0.1 M HClO₄ during a CV scan at 10 mV/s. The inset shows potential-dependent changes at 453 μm and 680 nm during the optically monitored voltammogram for both oxidative and reductive scans. FIG. 11 (b) shows in (a) in deaerated 0.1 M ⁿBu₄NPF₆/MeCN for reduction from −0.5 V (nanoITO-Ru^{II}(bpy)²⁺, red line) to −1.5 V (ITO|nanoITO-Ru^{II}(bpy⁻)⁺, blue line). The inset shows the time-dependent changes at 453 nm and 494 nm during the voltammogram.

FIG. 12 shows changes in absorbance with time at 453 nm and 680 nm during a potential step from 0.55 V vs. NHE to the potentials indicated in the figure. The electrolyte solution was 0.1 M HClO₄/H₂O (pH 1). Film thickness, ˜2.5 μm.

FIG. 13 shows the change in absorbance at 453 nm and 680 nm during potential pulse between 0.55 V and 1.45 V vs. NHE at a potential pulse width 5 s for 1 h. The spectra were recorded at the 4th sec of the 5 second pulse at each potential. The electrolyte solution was 0.1 M HClO₄/H₂O (pH 1). Film thickness, ˜2.5 μm.

FIG. 14 (a) shows photoluminescence data for unsensitized and sensitized (a) nanoITO. FIG. 14(b) shows nanoTiO₂ film upon 440 nm excitation. The characteristic Ru^{II} emission that is observed in the sensitized nanoTiO₂ film is completely quenched in the sensitized nanoITO film, while both samples had a decrease in scattering as a result of competitive absorption of the sensitizer. Film thickness, ˜2.5 μm.

FIG. 15 shows cyclic voltammogram of ITO|nanoITO|[Ru(Mebimpy)(4,4′-((HO)₂OPCH₂)₂ bpy)(OH₂)]²⁺ (Mebimpy is 2,6-bis(1-methylbenzimidazol-2-yl)pyridine) at pH 1 (0.1 M HNO₃). Scan rate, 10 mV/s. The dotted line is the ITO|nanoITO background under the same experimental conditions.

FIG. 16(a) demonstrates UV-vis-near IR spectrum and SEM images of oxidized ITO|nanoITO. FIG. 16(b) shows UV-vis-near IR spectrum and SEM images of reduced ITO|nanoITO.

FIG. 17(a) demonstrates UV-vis spectra of ITO|nanoITO|1-PO₃H₂ after various soaking time in 0.1 mM [Ru(bpy)₂(4,4′-PO₃H₂-bpy)]²⁺ solution in methanol. FIG. 17(b) demonstrates dependence of the absorbance at 493 nm on the soaking time at the thickness, ˜2.5 μm. Γₒ=1.7×10⁻⁸ mol/cm² (2.5 μm, 6.8×10⁻⁹ mol/cm²·μm). FIG. 4(c) shows adsorption isotherm for 1-PO₃H₂ on ITO|nanoITO after soaking in methanol stock solution of different concentration for 72 h at 25° C.

FIG. 18(a) shows CV of ITO|nanoITO|1-PO₃H₂ at pH 5 (I=0.1 M, CH₃CO₂H/CH₃CO₂Na; scan rate, 10 mV/s). The dotted line is the ITO|NanoITO background under the same experimental conditions. The inset shows CVs of ITO|NanoITO|1-PO₃H₂ at pH 5 before (blue line) and after (red line) scanning to 1.85 V. FIG. 18(b) shows electrolysis of ITO|NanoITO|1-PO₃H₂ at 1.85 V vs NHE at pH 5. Number of turnovers≈800, turnover frequency≈0.027 s⁻¹ (background subtracted). Γ=1.65×10⁻⁸ mol/cm², area=1.25 cm², current density 170 μA/cm².

FIG. 19 (a) shows normalized cyclic voltammograms of ITO|nanoITO|1-PO₃H₂ at pH 5 (0.036 M CH₃CO₂H-0.064 M CH₃CO₂Na) at different scan rates. The currents are normalized for scan rate, i/ν. FIG. 18 (b) shows dependence of the current of the Ru(III/II) redox couple at ITO|nanoITO|1-PO₃H₂ on the scan rate.

FIG. 20 shows square wave voltammogram of RuIV(OO)²⁺ (generated by adding ×3 Ce(IV) to 0.5 mM Ru^{II}-OH₂²⁺) in 0.1 M HNO₃ at a glassy carbon electrode. Incremental potential at each point, 0.004 V; square wave amplitude, 0.025 V; square wave frequency, 15 Hz. The dotted line represents the square wave voltammogram before Ce(IV) oxidation.

FIG. 21 (a) shows the cyclic voltammograms of ITO|nanoITO|1-PO₃H₂ at pH 3 (0.1 M phosphate buffer) before (blue line) and after (red line) scanning to 1.85 V. Scan rate, 10 mV/s; Γ=1.8×10⁻⁹ mol/cm² (2.5 μm, 7.2×10⁴⁰ mol/cm²⁻μm). FIG. 21(b) shows the dependence of the electrocatalytic current (nanoITO background subtracted) at 1.85 V vs NHE at pH 5 (0.036 M CH₃CO₂H-0.064 M CH₃CO₂Na) on surface complex loading. Scan rate, 10 mV/s.

FIG. 22 shows a proposed mechanism of electrocatalytic water oxidation by the single-site water oxidation catalyst 1-PO₃H₂ on oxide surfaces at pH 5.

FIG. 23(a) shows the cyclic voltammogram of ITO|nanoITO|1-PO₃H₂ at pH 1 (0.1 M HNO₃) at a scan a rate of 10 mV/s. The dotted line is the ITO|nanoITO background under the same experimental conditions. The inset shows cyclic voltammograms of ITO|nanoITO|1-PO₃H₂ at pH 1 before (blue line) and after (red line) scanning to 1.85 V. FIG. 15 (b) shows the electrolysis of ITO|nanoITO|1-PO₃H₂ at 1.85 V vs NHE at pH 1. Number of turnovers≈180, turnover frequency≈0.006 s⁻¹ (background subtracted). Γ=1.7μ¹⁰⁻⁸ mol/cm², area=1.25 cm², current density≈40 μA/cm² (16 μA/cm²·μm).

FIG. 24 shows the spectral evolution of ITO|nanoITO|1-PO₃H₂ at pH 1 (0.1 M HNO₃) during CV scans between: (a) 0-1.1 V, (b) 0-1.4 V, and (c) 0-1.85 V. The monitoring wave lengths are λₘₐₓ=493 nm for Ru^{II}-OH₂²⁺ and Ru^{II}(HOOH)²⁺ (red line), and λₘₐₓ=650 nm for Ru^{III}—OH₂³⁺ and R^{III}—OOH²⁺ (blue line). Scan rate, 10 my s⁻¹. For clarity, the blue line in (c) was magnified by 5-fold.

FIG. 25 shows UV-vis spectra of ITO|nanoITO|1-PO₃H₂ (red line), and following potential scans to 1.1 V (green line), 1.40 V (blue line) and 1.85 V (magenta line) vs NHE. Solution, pH 1 (0.1 M HNO3); scan rate, 10 mV/s.

FIG. 26 shows changes in absorbance of ITO|nanoITO|1-PO₃H₂ at 493 nm and 650 nm with time during a potential step from 0.30 V vs NHE to the potentials indicated in the figure, followed by step backward to 0.30 V. Solution, pH 1 (0.1 M HNO₃).

FIG. 27(a) shows the spectra evolution of FTO|nanoTiO₂|1-PO₃H₂ at pH 1 (0.1 M HNO₃) during CV scan between 0.2-1.1 V. The monitoring wave lengths are λmax=493 nm for Ru^{II}—OH₂²⁺ (red line), and λmax=650 nm for Ru^{III}—OH₂³⁺ (blue line). Scan rate, 10 mV/s. nanoTiO₂ Γ=5.3μ¹⁰⁻⁸ mol/cm² (10 μm, 5.3μ10⁻⁹ mol/cm²·μm). Only 8% of the available sites were electroactive as calculated from the absorption decrease at λmax=493 nm during 10 mV/s cyclic scan. (b) Absorbance change (493 nm) of FTO|TiO₂|1-PO₃H₂ at pH 1 (0.1 M HNO₃) with potential hold at 0.95 V vs NHE past E_{1/2} for RuIII-OH₂³⁺/RuII-OH₂²⁺ couple.

FIG. 28 shows the interfacial alcohol oxidation by nanoITO|1-PO₃H₂ with R^{IV}═O²⁺ and Ru^{V}═O³⁺.

FIG. 29 shows UV-visible monitoring of the reaction between BzOH, (46 mM), and nanoITO|Ru^{IV}═O²⁺ (see text) in pH 5, 0.1M aqueous acetate buffer at 25±2° C. illustrating the appearance of an initial intermediate at λₘₐₓ=495 nm followed by nanoITO|Ru^{II}—OH₂²⁺ at λₘₐₓ=493 nm. The inset shows an analysis of the data by using a biexponential A→B→C model and the software package SPECFIT 32, for the concentrations of A, B and C, with A=nanoITO|-Ru^{IV}═O²⁺, B an intermediate (see text and Equation 1b), and C=nanoITO|Ru^{II}—OH₂²⁺.

FIG. 30 shows Top: UV-Visible Spectrum of the A->B->C reaction with fitting parameters between 370 and 700 nm, as described by Equation 2. Bottom: Kinetic fit (green line) under pseudo-first order conditions (46.3 mM BzOH, red line) at 494 nm.

FIG. 31 shows spectra for Ru(III) species generated by the addition of 1 eq of Ce(IV) to Ru^{II}(tpy′)(bpy)(OH₂). Black line: Ru(III)-OH at pH 5. Red line: Ru(III)-OH₂ at pH 1 (see FIG. 32 for pKa values).

FIG. 32 shows slow scan CV (1 mV/s) in the presence of BzOH. The new peak at 1.32 V (NHE), is attributable to a Ru^{II} intermediate, Equation 2.

FIG. 33 shows E_{1/2}-pH diagram for nanoITO|Ru^{II}—OH₂²⁺.

FIG. 34 shows CVs of nanoITO-1-PO₃H₂ at pH 5 (I=0.1 M acetate buffer at 25±2° C.) with addition of increasing amounts of BzOH. The inset shows a plot of i_{cat} (background subtracted) at 1.6 V (vs NHE) vs [BzOH] (note Eqs. 2a-b) Scan rate 10 mV/s (A=1 cm²).

FIG. 35 shows controlled potential electrolysis of 6.5 mM isopropanol at pH 5 (0.1M acetate) by nanoITO|Ru^{V}═O³⁺ at 1.55 V (NHE) for 50,000 s.

### DETAILED DESCRIPTION

The foregoing and other aspects of the present invention will now be described in more detail with respect to the description and methodologies provided herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise. Also, as used herein, “and/or” refers to and encompasses any and all possible combinations of one or more of the associated listed items. Furthermore, the term “about,” as used herein when referring to a measurable value such as an amount of a compound, dose, time, temperature, and the like, is meant to encompass variations of 20%, 10%, 5%, 1%, 0.5%, or even 0.1% of the specified amount. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise defined, all terms, including technical and scientific terms used in the description, have the same meaning as commonly understood by one of ordinary skill in the art to which this invention belongs.

All patents, patent applications and publications referred to herein are incorporated by reference in their entirety. In case of a conflict in terminology, the present specification is controlling.

A. Electrodes

One aspect of the present invention relates to electrodes comprising (a) a supporting substrate and (b) nanoparticle composition comprising optically transparent conductive nanoparticles on the substrate. As used herein, “optically transparent” is defined as at least about 50% of visible light transmittance there through. In some embodiments, the optically transparent is at least about 70% of visible light transmittance there through.

As used herein, “electrode” is an electrical conductor used to make contact with a nonmetallic part of a circuit (e.g. a semiconductor, an electrolyte or a vacuum).

Exemplary nanoparticles include, but are not limited to, tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide and aluminum zinc oxide (AZO) nanoparticles and combinations thereof. In one embodiment, the nanoparticles are tin-doped indium oxide (ITO) nanoparticles.

In some embodiments, the average diameter of nanoparticles is less than about 80 nm. In another embodiment, the average diameter of the nanoparticles is less than about 40 nm. Further, in one embodiment, the total surface area of the electrode is about 1, 2, 5, 10, 50, 100, 500 to 5000 or 10000 times more than the total surface area of the electrode made of the same material that is not in the form of nanoparticles. In one embodiment, the nanoparticle composition is in a form of nanoparticles coating on the support substrate. In another embodiment, the resistance of the electrode is inversely correlated with the thickness of the nanoparticle film.

Any applicable support substrate may be used in the present invention. In one embodiment, the support substrate comprises conductive material. Exemplary support substrate includes, but is not limited to, tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide, aluminum zinc oxide (AZO) and a combination thereof.

In another embodiment, the electrode may be used for electrolysis of water molecules. In one embodiment, the electrode may be used for photo-electrolysis of water molecules.

In some embodiments, the electrode may be an anode or a cathode. For example, the catalysts described herein are added to the surfaces of conducting oxide substrates where oxidation or reduction occurs by application of an electrical potential or on photoanodes or photocathodes where the required potential is created by light absorption and electron transfer. It is observed by the investigators of the present application that the surface bound complex of the catalyst comprising compounds described herein retains its chemical (E_{1/2} values, pH dependence) and physical properties (UV-visible spectra) including its ability to catalyze water oxidation. In some embodiments, electrocatalysis reaction catalyzed by catalysts described herein may occur on TiO₂ which has been used in dye-sensitized solar cells.

The electrodes may be prepared according to, any applicable methods known to one skilled in the art. For example, U.S. Pat. No. 4,797,182 to Beer et al., U.S. Pat. No. 4,402,996 to Gauger et al., U.S. Pat. No. 7,320,842 to Ozaki et al., and U.S. patent application no. 20090169974, which are incorporated by references in their entireties.

B. Transition Metal Catalysts

In one aspect, the nanoparticle electrodes described herein may further comprise at least one transition metal catalyst. Any appropriate transition metal catalyst known to one skilled in the art may be used in the present invention. In some embodiments, the catalyst is a Ruthenium, Iridium, or Osmium catalyst.

Exemplary catalysts include, but are not limited to, complexes having the structure of formula (I):

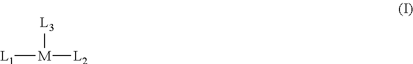

wherein M is Ruthenium (Ru), Iridium (Ir), Iron (Fe), Cobalt (Co), Nickel (Ni) or Osmium (Os), and L₁, L₂ and L₃ may be any combinations of any ligands as long as the combination meets the bonding requirement for M. In some embodiments, L₁ may be any applicable bidentate ligand that is known to one skilled in the art, L₂ may be any applicable tridentate ligand that is known to one skilled in the art and L₃ may be any applicable monodentate ligand that is known to one skilled in the art. In one embodiment, L₃ is H₂O. According to the investigators of the present application, the considerations of selecting the ligands include, but are not limited to, the following: (1) the stability toward oxidation by the high oxidation state oxo forms of the catalysts; (2) ability electronically to provide the metal (e.g. Ru or Os) to access higher oxidation state IV and V oxidation states by oxo formation; and (3) the resulting potential for multi-electron oxidation of water being sufficient to be thermodynamically allowed.

As used herein, a ligand is either an atom, ion, or molecule that binds to a central metal to produce a coordination complex. The bonding between the metal and ligand generally involves formal donation of one or more of the ligand's electrons. The monodentate ligand is a ligand with one lone pair of electrons that is capable of binding to an atom (e.g. a metal atom). Exemplary monodentate ligands include, but are not limited to, H₂O (aqua), NH₃ (ammine), CH₃NH₂ (methylamine), CO (carbonyl), NO (nitrosyl), F⁻ (fluoro), CN⁻ (cyano), Cl (chloro), Br⁻ (bromo), I⁻ (iodo), NO₂⁻ (nitro), and OH⁻ (hydroxyl). In some embodiments, the monodentate ligand is H₂O. The bidentate ligand is a ligand with two lone pairs of electron that are capable of binding to an atom (e.g. a metal atom). Exemplary bidentate ligands include, but are not limited to, bipyridine, phenanthroline, 2-phenylpyridine bipyrimidine, bipyrazyl, glycinate, acetylacetonate, 2,6-bis(1-methylbenzimidazol-2-yl)pyridine (mebim-py) and ethylenediamine. The tridentate ligand and terdentate ligand is a ligand with respectively three or four lone pairs of electron that are capable of binding to an atom (e.g. a metal atom). Exemplary tridentate ligands include, but are not limited to, terpyridine, DMAP, and Mebimpy.

The terminology of monodentate ligand, bidentate ligand, and tridentate ligand are well known to those skilled in the art. Further exemplary monodentate ligand, bidentate ligand, and tridentate ligand are described in U.S. Pat. Nos. 7,488,817, 7,368,597, 7,291,575, 7,232,616, 6,946,420, 6,900,153, 6,734,131, 4,481,184, 4,019,857, and 4,452,774, which are incorporated by references in their entirety.

The bidentate ligands and tridentate ligands used in the present invention may be optionally substituted with one or more substituents. Any applicable substituents may be used. Exemplary substituents include, but are not limited to, carboxylic acid, ester, amide, halogenide, anhydride, acyl ketone, alkyl ketone, acid chloride, sulfonic acid, phosphonic acid, nitro and nitroso groups. The substituents may be located at any acceptable location on the ligand and may include any number of substituents which may be substituted on the particular ligand.

More exemplary L₁ include, but are not limited to,

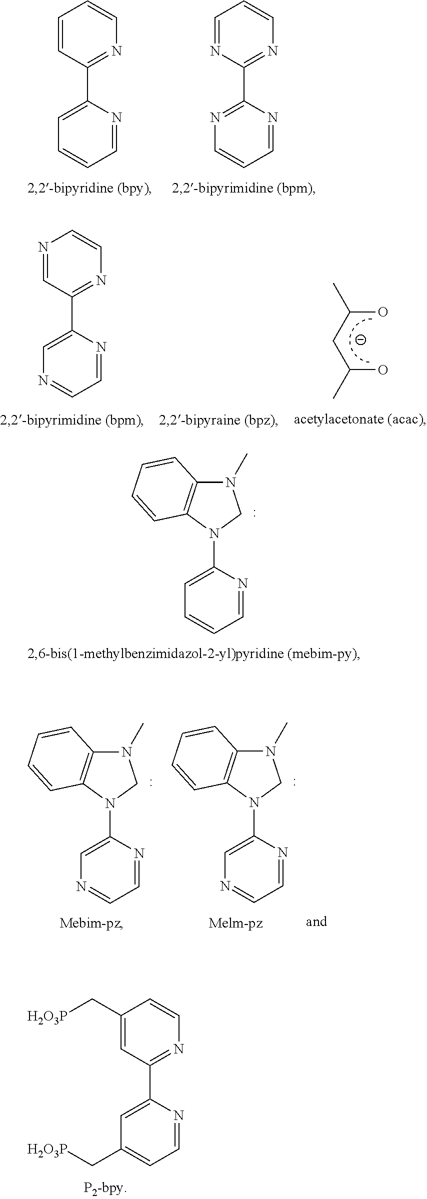

More exemplary L₂ include, but are not limited to,

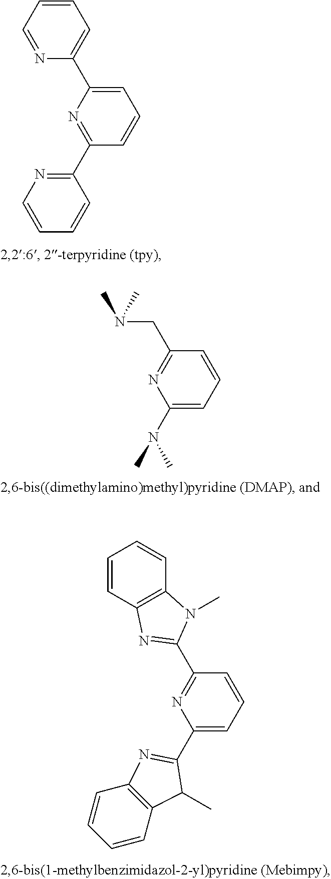

The complexes provided according to some embodiments of the invention is

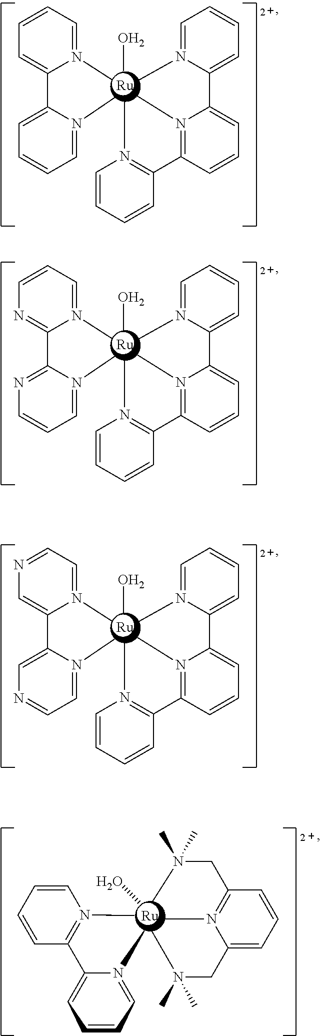

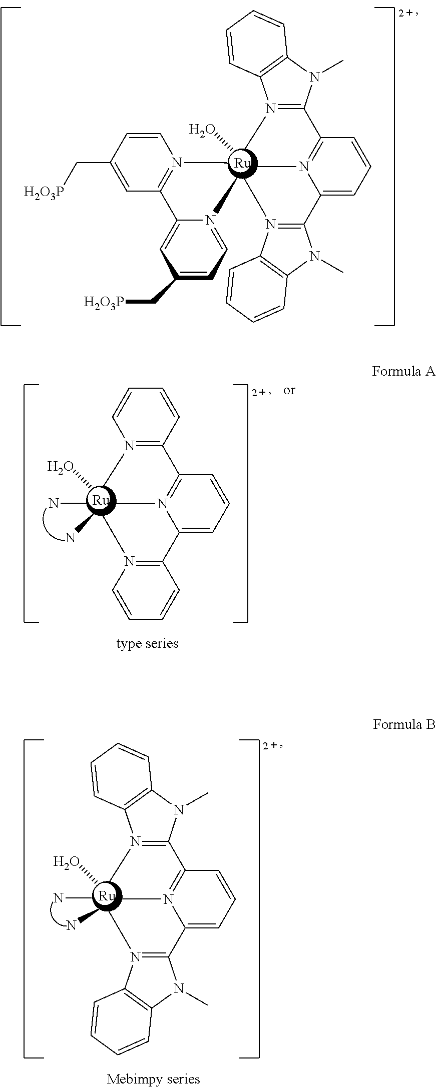

wherein: for formula A and B

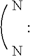

is independently selected from

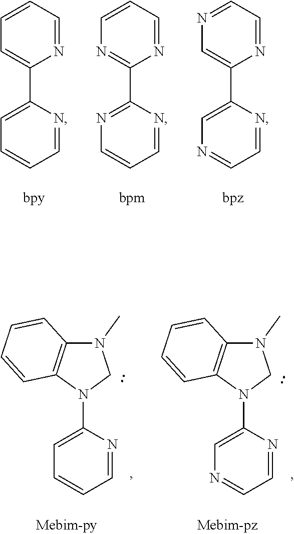

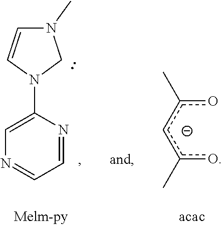

In one embodiment, the complex is

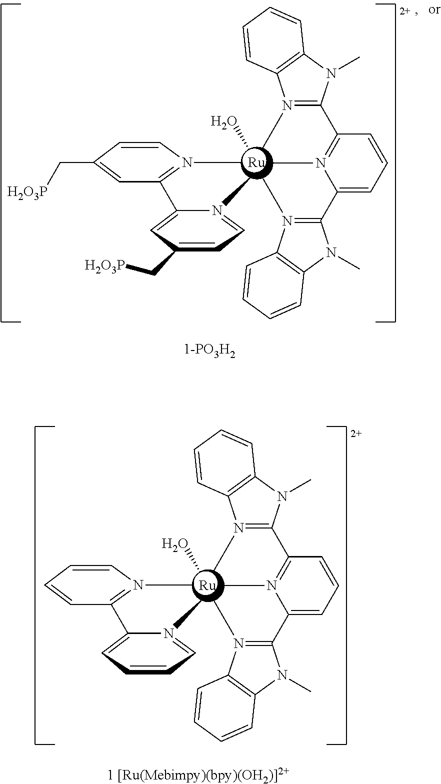

In one embodiment, the catalyst is a transition metal complex comprising at least one phosphonated derivatized ligand. Exemplary ligand includes, but is not limited to, phosphonated polypyridyl, 4,4′-PO₃H₂-bpy, 4,4′-((HO)₂OPCH₂)₂bpy, 4,4′-diphosphonato-2,2′-bipyridine and 4,4′-methylenediphosphonato-2,2′-bipyrid. In one embodiment, the catalyst comprises [Ru(bpy)₂(4,4′-PO₃H₂-bpy)](PF₆), or [Ru(Mebimpy)(4,4′-((HO)₂OPCH₂)₂bpy)(OH₂)]²⁺ (Mebimpy is 2,6-bis(1-methylbenzimidazol-2-yl)pyridine). In one embodiment, the phosphonated derivatized ligand is selected from the group consisting of

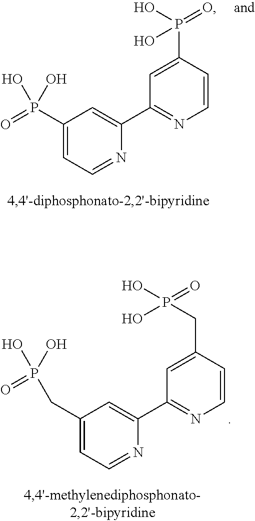 [SMILES: O=P(O)(O)c1ccnc(-c2cc(P(=O)(O)O)ccn2)c1 ; O=P(O)(O)Cc1ccnc(-c2cc(CP(=O)(O)O)ccn2)c1]

The transition metal catalysts described herein may be prepared by using methods described in the literature with modifications known to one skilled in the art.

For example, [Ru(tpy)(NN)(OH₂)]ⁿ complexes with NN=bpy, bpm, bpz and acac may be prepared according to methods known to one skilled in the art. (See Concepcion, et al., J. Am. Chem. Soc. 2008, 130(49), 16462-16463, Dovletoglou, et al., Inorg. Chem. 1996, 35(14), 4120-4127, Takeuchi, et al., Inorg. Chem. 1984, 23(13), 1845-1851, and Takeuchi, et al., Inorg. Chem. 1984, 23(13), 1845-1851.)

The synthesis of the [Ru(Mebimpy)(NN)(OH₂)]ⁿ⁺ complexes with LL=bpy, bpm, bpz and acac may be accomplished following procedures similar to those used for the corresponding tpy complexes discussed above. They may involve isolation of the [Ru(Mebimpy)(NN)(Cl)]ⁿ⁺ complexes followed by replacement of the chloro ligand in water assisted by added silver triflate or triflic acid. The trans-[Ru(tpy)(NN)(OH₂)]²⁺, trans-[Ru(Mebimpy)(NN)(OH₂)]²⁺ complexes and trans-[Ru(DMAP)(NN)(OH₂)]²⁺ (NN is 3-methyl-1-pyridylimidazol-2-ylidene, MeIm-py; 3-methyl-1-pyridylbenzimidazol-2-ylidene, Mebim-py; and 3-methyl-1-pyridylbenzimidazol-2-ylidene, Mebim-pz) may be obtained by reaction of the monocationic carbene precursors with Ru(tpy)Cl₃, Ru(Mebimpy)Cl₃ or Ru(DMAP)Cl₃₇ in ethyleneglycol at 150° C. in the presence of. NEt₃. (See Sullivan et al., Inorg. Chem. 1980, 19(5), 1404-1407, Welch, et al., Inorg. Chem. 1997, 36(21), 4812-4821.) In these cases the aquo complexes are isolated rather than chloro complexes most likely due to a trans-labilizing effect of the carbene on chloride ligand loss, since only the trans isomer is obtained. For example, [Ru(Mebimpy)(4,4′-((OH)₂OPCH₂)²⁻ bpy)(OH₂)]²⁺ may be prepared by a modification of the procedure used to synthesize [Ru(Mebimpy)(bpy)(OH₂)]²⁺ with an extra step required to hydrolyze the phosphonate esther groups. Ru(DMAP)(bpy)(OH₂)²⁺ may be prepared following a literature procedure.

C. Dye Compounds

In another aspect, the nanoparticle electrodes described herein may further comprise at least one dye compound, which is on the surface of the nanoparticles. Any appropriate dye compounds known to one skilled in the art may be used in the present invention. Exemplary chromophores of dye compounds include, but are not limited to, carboxylic acid, phosphonic acid, silane, substituents for surface attachment, and the chromophoric portion of the compound may include, but are not limited to, the monomers, oligomers, or polymers of the following: porphyrins, pyrenes, perylenes, coumarins, rhodamines, buckminsterfullerenes, thiophenes, Ruthenium polypyridyl complexes, ferrocenes, methyl viologen, and combinations thereof. Any appropriate combinations of chromophores and chromophoric to form the dye compounds may be applied to the present invention. In some embodiments, the structure and property of the dye compounds may vary depending on the different preparation methods of the dye compounds. Other exemplary dye compounds include, but are not limited to, those described in U.S. Pat. No. 7,569,704, 7,442,780, 7,166,715, 6,306,192, 5,210,200, 5,084,571, 4,772,530, 4,751,102 or 4,554,348, which are incorporated by references in their entireties.

D. Methods of Preparing Nanoparticle Electrodes

Another aspect of the present invention provides methods preparing the electrodes described herein. The methods comprise: preparing a suspension of nanoparticles; applying the suspension of the nanoparticles to a support substrate; and annealing the supporting substrate with the nanoparticle for a period of time and at a temperature sufficient to produce a nanoparticle film on the electrode. The nanoparticles may be applied to the supporting substrate by any suitable means, for example annealing process.

In one embodiment, the methods further comprise the step of dispersing the suspension evenly before the step of applying the suspension of nanoparticles to a support substrate. In some embodiments, the step of dispersing is carried out by sonicating the suspension for a sufficient time such that the majority of the particles are evenly dispersed. The “majority of particles” refers to at least 50, 60, 70, 80 90 or 100% of the particles.

Further, in one embodiment, the annealing step is carried out at least twice and at different temperature ranges. In some embodiments, the first annealing step is carried out at a temperature in a range of about 500° C. to about 1000° C. In some embodiments, the first annealing step is carried out at a temperature in a range of about 500° C. to about 700° C. In a different embodiment, the first annealing step is carried out under atmospheric conditions. In one embodiment, the first annealing step is carried out for about at least 30 mins, 1 hour, 2 hour or 3 hour. In one embodiment, the second annealing step is carried out at a temperature in a range of about 300° C. to about 500° C. In one embodiment, the second annealing step is carried out in a gas comprising hydrogen and an inert gas. Exemplary gas includes, but is not limited to helium, argon, nitrogen, and a combination thereof. In one embodiment, the inert gas is nitrogen. Any suitable amount of insert gas may be presented in the mixture of gas. However, in one embodiment, the mixture of gas includes about 1 to 10% of hydrogen in the total weight. In one embodiment, the mixture of gas includes about 1% to 3% of hydrogen in the total volume of the mixture of gas. In another embodiment, the second annealing step is carried out for at least about 30 mins, 1, 2 or 3 hour.

In one embodiment, the methods described herein further comprise adding polymer to the suspension of nanoparticles. In another embodiment, for the methods described herein, the nanoparticle film formed on the electrode has a thickness in a range of about 50-100 micron.

Further, in one embodiment, the methods comprise exposing the nanoparticle film to a solution of a transition metal catalyst for a sufficient time such that the surface of the nanoparticle compositions is saturated with the catalyst. In one embodiment, the nanoparticle film may be exposed to a solution of a transition metal catalyst for about less than 3 hours; The degree of saturation of the catalyst may be determined by any methods known to one skilled in the art. Exemplary methods of determining degree saturation are described in Example II of the application.

E. Control of Porosity of Nanoparticle Composition

The porosity of the nanoparticle composition may be increased by adding polymer to the ITO nanoparticle ethanol/acetic acid dispersions that are used for preparing thin films. During the high temperature anneal process, the polymer may be burned off. In one embodiment, the porosity increases as the amount of polymer increases. The addition of polymer may result in ITO nanoparticle dispersions with higher viscosities which may result in thicker thin films deposited by spin-coating. Using this approach, 10-30 micron thick films that display two-point resistances that are similar to 3 micron films without polymer were prepared. FESEM images show that the films prepared with the addition of polymer are more porous than those without polymer. In some embodiments, the thickness of the film is in the range of about 50-100 micron. In one embodiment, the polymer is fully saturated and composed of C, H, and O to allow for complete removal during the high temperature anneal. In another embodiment, the polymer is fully soluble in the solvent mixture used to create the nanoparticle suspension.

F. Industrial Applications for Nanoparticle Electrodes

In one embodiment, the nanoITO films described herein possess high surface area, optical transparency, and high electrical conductivity. The films may be used for optical monitoring of voltammograms and electrocatalysis and real time spectroscopic measurement of electrochemical reactions and intermediates. In addition, the films may be applied to electrochromic, display, and photovoltaic applications due to the wide potential window and relatively rapid electron transfer characteristics of the films.

According to some embodiments, the electrodes described herein may be used in electrochromic devices (e.g., flat panel displays). In one embodiment, a potential may be applied to reversibly oxidize/reduce the species (e.g., organometallic catalyst) bound to the surface of the nanoparticle composition described herein. Then, the reduction/oxidation process may be associated with a significant spectral/color change which allows for use in display applications.

According to another aspect of the invention, the electrodes described herein may be in electrocatalytic transformations. For example, in a water oxidation or electrocatalytic reaction, water oxidation catalysts (e.g., such as molecular-level Ruthenium catalysts) may be adsorbed to the surface of nanoITO. Then, an electrochemical potential may be applied to generate active catalysts that allow the four electron oxidation of water to oxygen and protons.

A further aspect of the present invention provides an electrochemical cell for the electrolysis of water molecules comprising a container and at least one electrode described herein in the container.

As used herein, photo-electrochemical cell is referred to as solar cells which generate electrical energy from light, including visible light. In some embodiments, the visible light is used for chemical conversion reactions at separate electrodes. The photo-electrochemical cell may be prepared according to any applicable methods known to one skilled in the art, for example, U.S. Pat. No. 4,388,384 to Rauh et al., U.S. Pat. No. 4,793,910 to Smotkin et al., U.S. Pat. No. 5,525,440 to Kay et al., and U.S. Pat. No. 6,376,765 to Wariishi et al., which are incorporated by references in their entireties.

One aspect of the present invention provides a light-emitting diode (LED) comprising an electrode described herein.

A further aspect of the present invention provides methods of generating hydrogen (H₂) and oxygen (O₂) gases by photo-electrolyzing water. In one embodiment, the methods comprise exposing the photo-electrochemical cell described herein to light radiation to generate hydrogen and oxygen gases without the requirement of applying an external electrical potential.

Another aspect of the present invention provides methods of generating hydrocarbons and/or methanol and oxygen (O₂) gases by photo-electrolyzing water. In one embodiment, the methods comprise exposing the photo-electrochemical cell described herein to light radiation without the requirement of applying an external electrical potential.

One aspect of the present invention provides a solar cell comprising at least one electrode described herein. In some embodiments, the present invention provides photon-to-fuel dye-sensitized photoelectrochemical cells (DS-PEC) that comprise at least one electrode described herein. In another embodiment, the present invention provides photon-to-electricity cases (dye-sensitized solar cells (DSSCs) that comprise at least one electrode described herein. Further, in one embodiment, the present invention provides organic photovoltaic devices (OPV)) that comprises at least one electrode described herein.

Another aspect of the present invention provides an electrochromic device comprising at least one electrode described herein, and at least one electrode further comprising a transparent or translucent substrate coated with a nanoparticle composition selected from the group consisting of tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide and aluminum zinc oxide (AZO) and a combination thereof.

A further aspect of the present invention provides an energy storage device or capacitor, comprising at least one layer comprising nanoparticle composition selected from the group consisting of tin-doped indium oxide (ITO), fluorine doped tin oxide (FTO), antimony tin oxide (ATO), gallium zinc oxide (GZO), indium zinc oxide (IZO), copper aluminum oxide, fluorine-doped zinc oxide and aluminum zinc oxide (AZO) and a combination thereof. For example, the nanoparticle compositions described herein may be used as high surface area electrical conductor in fuel cells or capacitors (e.g. ultracapacitors).

A further aspect of the present invention provides a real time spectrophotometric/color monitoring device of surface phenomena caused by applied potential changes to the electrodes described above.

The present invention will now be described in more detail with reference to the following examples. However, these examples are given for the purpose of illustration and are not to be construed as limiting the scope of the invention.

### EXAMPLES

### General Information

Chemicals. Perchloric acid (HClO₄, 70%, redistilled, trace metal grade) and tetra-n-butylammonium hexefluorophosphate (ⁿBu₄NPF₆, ≧99%) was purchased from Sigma-Aldrich and used as received. [Ru(bpy)₂(4,4′-PO₃H₂-bpy)](PF₆)₂ was prepared according to a literature procedure (Montalti, et al., Inorganic Chemistry 2000, 39, 76). ITO electrodes (ITO-coated glass, R_{ε}=4-8 ohms) were obtained from Delta Technologies, Limited. NanoITO powder was obtained from Lihochem, Inc. Other chemicals were analytical reagent graded and used as received. All solutions were prepared with deionized water (Milli Q, Millipore).

Apparatus. Field emission scanning electron microscopy (FESEM) was performed on a Hitachi 4700. UV-Vis spectra were recorded on an Agilent Technologies Model 8453 diode-array spectrophotometer. Emission spectra were recorded on a Photon Technology International Inc. QuantaMaster 4SE-NIR5 with a Hamamatsu R928P PMT. Film thicknesses were measured with a Tencor Alpha Step profilometer. Electrochemical measurements were performed on an EG&G Princeton Applied Research Potentiostat/Galvanostat Model 273A. The three-electrode system consisted of a nanoITO slide (typically ˜1-2 cm²) working electrode, a coiled Pt wire counter electrode, and Ag/AgCl (aqueous) or Ag/AgNO₃ (non-aqueous) reference electrodes. All the potentials reported are vs NHE.

### Example I

### NanoITO Electrodes

### (a). Preparation of NanoITO Electrodes

Acetic acid (3 g) was added to 200 proof ethanol (10 mL) to afford a 5 M solution. NanoITO was then added via powder funnel (for 12 wt %, 1.5 g of the powder was added; for 22 wt %, 3 g was added, etc.). This mixture was sonicated for 20 minutes after manual shaking. The colloidal suspension was shaken further manually so that none of the powder remained at the bottom of the vial. The colloidal suspension was poured into a tall 25 mL beaker and sonicated using a Branson ultrasonic horn flat microtip (70% power, 50% duty cycle; 2-5 minutes). The suspension was allowed to cool to room temperature before further use.

2.5 cm×2.5 cm glass substrates (ITO glass, FTO glass, or borosilicate glass) were prepared and cleaned by sonication in isopropanol for 20 min followed by acetone for 20 min. Kapton tape was applied to one edge to maintain an area (˜0.3 cm×2.5 cm) to later make direct electrical contact to the underlying TCO glass substrate. The substrate was then placed onto the spin chuck of a spin-coater. The nanoITO colloidal suspension was transferred to the substrate by Pasteur pipette so that the entire area was covered with the suspension. The sample was spun at 1000 rpm for 10 seconds, carefully removed from the spin coater, and placed on a hot plate at 100° C. for several minutes to remove residual solvent.

The resulting electrodes were placed in a tube furnace and annealed under atmospheric conditions by using the heating program below. The samples were slowly cooled to room temperature and annealed at 300° C. under a steady flow of 3% H₂/N₂ according to the heating program below. The samples were allowed to slowly cool to room temperature under H₂/N₂ and used with no further modification.

TABLE 1
Heating programs for NanoITO/glass slides.

| | Atmospheric conditions | H₂/N₂ |
|---|---|---|
| | (500° C.) | (300° C.) |
| Initial temperature | 20° C. | 20° C. |
| Ramp time to heating temperature | 2 h | 1.5 h |
| Time at heating temperature | 1 h | 1 h |

### (b) Various Properties of the Nanoelectrodes

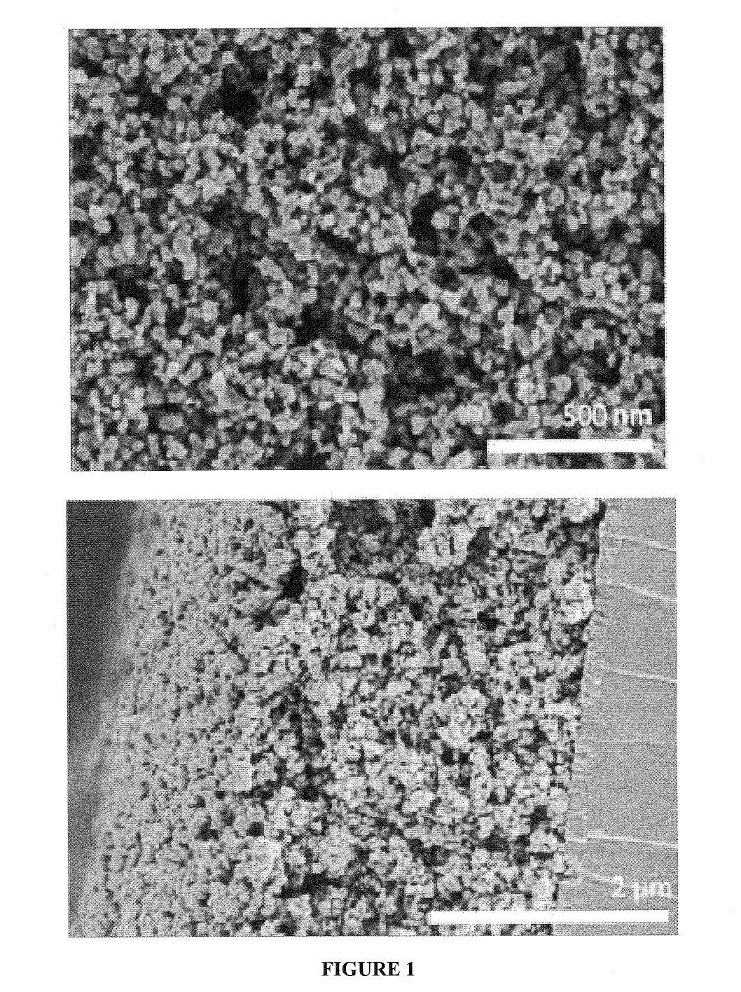

The top-down and cross-sectional field emission scanning electron microscope (FESEM) images is shown and demonstrate that the films are highly porous and uniform, allowing for the diffusion of solvent and electrolyte within the porous film structure. (See FIG. 1)

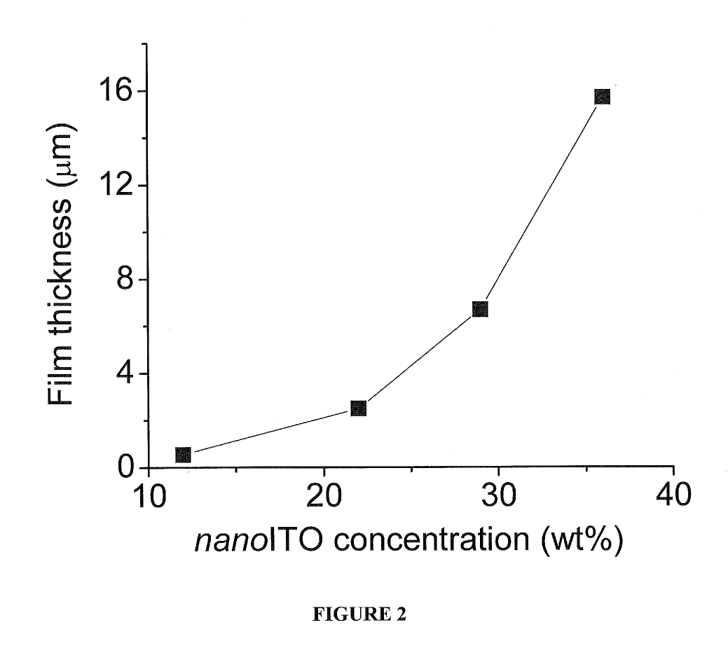

The thickness of the nanoITO composition layer may be controlled by varying ITO nanoparticle concentration in the suspension: 0.55 μm for 12 wt %, 2.5 μm for 22 wt %, 6.7 μm for 29 wt %, and 15.7 μm for 36 wt %. (See FIG. 2)

The resistance across 1 cm of a 0.55 μm thick film, annealed in air on glass, by two-point probe measurements was 31 kΩ; 1.7 kΩ for a 15.7 μm thick film. Hydrogen annealing decreased the resistance to 840Ω and 50Ω, respectively (See Table 2). A four-point probe measurement on the latter film gave 45Ω over an applied potential range of ±1 V. The effects of various annealing conditions are summarized in Table 3.

TABLE 2
Two-point resistance data for glass|nanoITO films with
thicknesses controlled by the concentration of nanoITO
in the suspension.

Two-point resistance

| Colloidal suspension | After annealing in | After annealing in |
|---|---|---|
| composition | air (500° C.) | 3% H₂/N₂ (300° C.) |
| 12 wt % in EtOH, | 31 kΩ | 840 Ω |
| 5M Acetic acid | | |
| 22 wt % in EtOH, | 7.0 kΩ | 220 Ω |
| 5M Acetic acid | | |
| 29 wt % in EtOH, | 2.4 kΩ | 70 Ω |
| 5M Acetic acid | | |
| 36 wt % in EtOH, | 1.7 kΩ | 50 Ω |
| 5M Acetic acid | | |

TABLE 3
Two-point resistance data for glass|nanoITO films with
thicknesses controlled by the concentration of nanoITO in
the suspension that were annealed under atmospheric
conditions at 500° C., followed by 700° C., and
finally 3% H₂/N₂ at 300° C. annealed.

| | | | | | After | | | |
|---|---|---|---|---|---|---|---|---|
| | After | | After | | annealing | | | |
| Colloidal | annealing | | annealing | | in 3% | | Average | |
| suspension | in air | | in air | | H₂/N₂ | | film | |
| composition | (500° C.) | | (700° C.) | | (300° C.) | | thickness | |
| 12 wt % in EtOH, | 31 | kΩ | 4.5 | kΩ | 530 | Ω | 530 | nm |
| 5M Acetic acid | | | | | | | | |
| 22 wt % in EtOH, | 7.0 | kΩ | 1.1 | kΩ | 130 | Ω | 2.5 | μm |
| 5M Acetic acid | | | | | | | | |
| 29 wt % in EtOH, | 2.4 | kΩ | 550 | Ω | 58 | Ω | 6.7 | μm |
| 5M Acetic acid | | | | | | | | |
| 36 wt % in EtOH, | 1.7 | kΩ | 850 | Ω | 75 | Ω | 15.7 | μm |
| 5M Acetic acid | | | | | | | | |

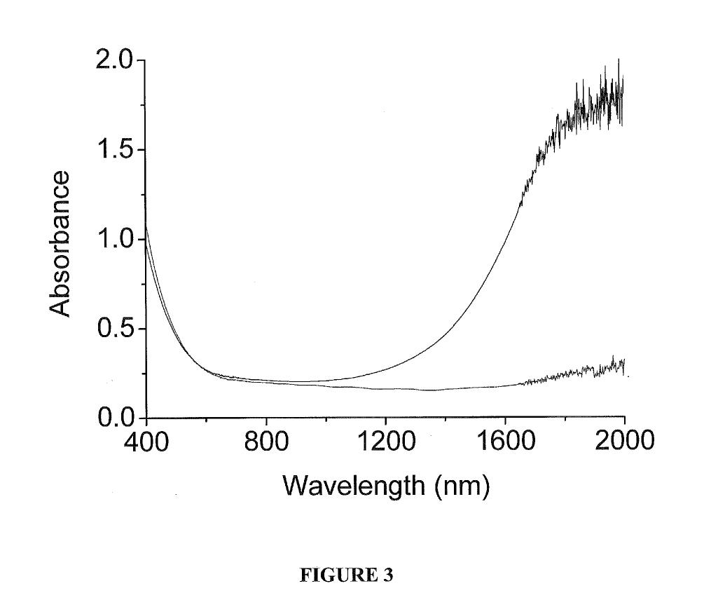

UV-visible-near IR measurements on dry nanoITO films, FIG. 3, show that underivatized films are largely transparent above 400 nm with an apparent near UV absorption that tails into the visible. This feature increases with film thickness and is attributable to light scattering by nanoparticle aggregates. Hydrogen annealed films have a bluish cast while films annealed under atmospheric conditions have a light yellow cast.

### Example II

### NanoFTO (F Doped SnO₂)

FTO nanoparticle thin films by preparing FTO nanoparticle dispersions using commercial FTO nanoparticles doped with 1% fluoride were prepared. The dispersion was spin coated onto FTO glass substrates and the films were annealed at 500° C. The films displayed very high two-point resistances in the mega-ohm range. These thin films were sensitized with a Ruthenium Bisphosphonate complex and the films were used as the working electrode in a three-electrode cell. Cyclic voltammetry experiments for the sensitized FTO nanoparticle thin films revealed current levels on par with FTO glass in the absence of nanoparticles. This suggests that there is minimal conduction along the z-direction of the thin film and is consistent with highly resistive, low conductivity films. The commercial material contains nanoparticles with a very broad particle size distribution, ranging from 20 nm to 500 microns. Monodisperse FTO nanoparticles may conduct better than polydisperse materials.

### Alternative Deposition Methods for Preparing High Surface Area Porous Conductive Thin Films

High surface area conductive thin films may be prepared using a physical vapor deposition technique such as pulsed laser deposition (PLD). In this technique, high energy laser pulses are directed at a target consisting of the transparent conductive oxide (TCO) material (e.g. FTO, FZO, copper aluminum oxide) under vacuum. The vaporized material is then deposited onto a nearby substrate to create thin films. Key variables in the process are substrate-target distance, laser wavelength, laser power, laser repetition rate, carrier gas, and the partial pressure of oxygen during the deposition process. The partial pressure of oxygen has been previously demonstrated to control the morphology and size of metal oxide particles as well as the morphology of the thin film. The doping levels of the TCO material may be fine-tuned to control the doping level of the deposited thin films (e.g. the F-content of FTO may be varied between 1-10 wt %). The doping level may be a variable for controlling the conductivity of the porous, high surface area TCO films. The PLD method offers a facile method to produce high surface area thin films of TCO materials that may not be readily attainable using sol-gel nanoparticle-based methods of preparation.

Other alternative deposition methods include, but are not limited to, the following: electron beam evaporation, RF sputtering, DC sputtering, layer-by-layer deposition, and electrophoresis.

### Example III

### nano ITO Film Functionalized with Ru Catalyst

(a) Preparation of nano ITO Film Functionalized with Ru Catalyst

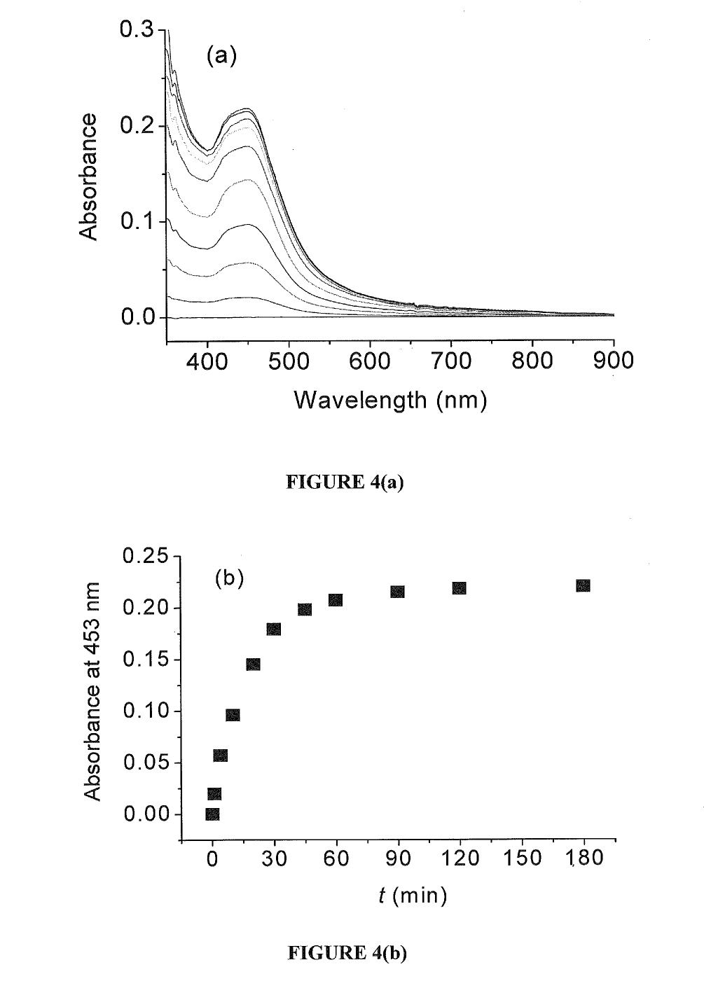

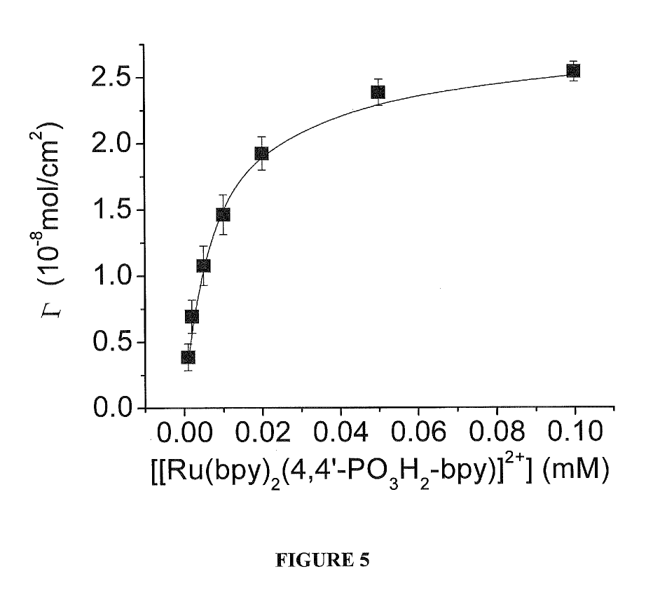

After exposing a nanoITO film on ITO (ITO|nanoITO) to a 0.1 mM methanolic solution of the phosphonate derivative salt, [Ru(bpy)₂(4,4′-PO₃H₂-bpy)](PF₆)₂ (4,4′-PO₃H₂-bpy is 4,4′-diphosphonate-2,2′-bipyridine), a characteristic Metal-to-Ligand Charge Transfer (MLCT) absorption band appears at λₘₐₓ=453 nm, FIG. 4. Complete surface coverages (Γₒ˜2.5×10⁻⁸ mol/cm²) were reached within 3 h for 2.5 μm film thicknesses. Surface coverages were estimated from the relationship, Γ′=A(λ)/(10³×ε(λ)), with A(λ) the absorbance at λ and ε(λ)=εₘₐₓ=9.0×10³ M⁻¹cm⁻¹ for [Ru(bpy)₂(4,4′-PO₃H₂-bpy)]²⁺ in methanol at 453 nm. Based on Langmuir isotherm measurements, FIG. 5, K=1.4×10⁵ M⁻¹ for surface binding in methanol at 25° C. as determined by spectrophotometric measurements (ε(453 nm) 9.0×10³ M⁻¹cm⁻¹ for [Ru(bpy)₂(4,4′-PO₃H₂-bpy)]²⁺ in methanol) and the relationship, Γ=Γₒ[M]/([M]+1/K). In this equation Γₒ is the coverage for a fully loaded surface and Γ is the equilibrium coverage at molar concentration [M].

Adsorbed [Ru(bpy)₂(4,4′-PO₃H₂-bpy)]²⁺ in films of nanoITO on conducting ITO, ITO|nanoITO-Ru^{II}, is relatively stable on the surface. On the basis of UV-visible measurements, there was no loss of complex after soaking in 0.1 M HClO₄ for 15 h while 10% of the complex was lost after 4 days in neutral, deionized water. As expected, surface coverages increase linearly with film thickness, from 5.5×10⁻⁹ mol/cm² (0.55 μm) to 1.6×10⁻⁷ mol/cm² (15.7 μm). At 0.55 μm the effective sensitizer surface coverage is ˜34 times greater than for planar FTO or ITO electrodes (˜1.6×10⁻¹⁰ mol/cm², increasing to ˜1000 times for 15.7 μm films.

(b) Measurements of nanoITO-R^{II}

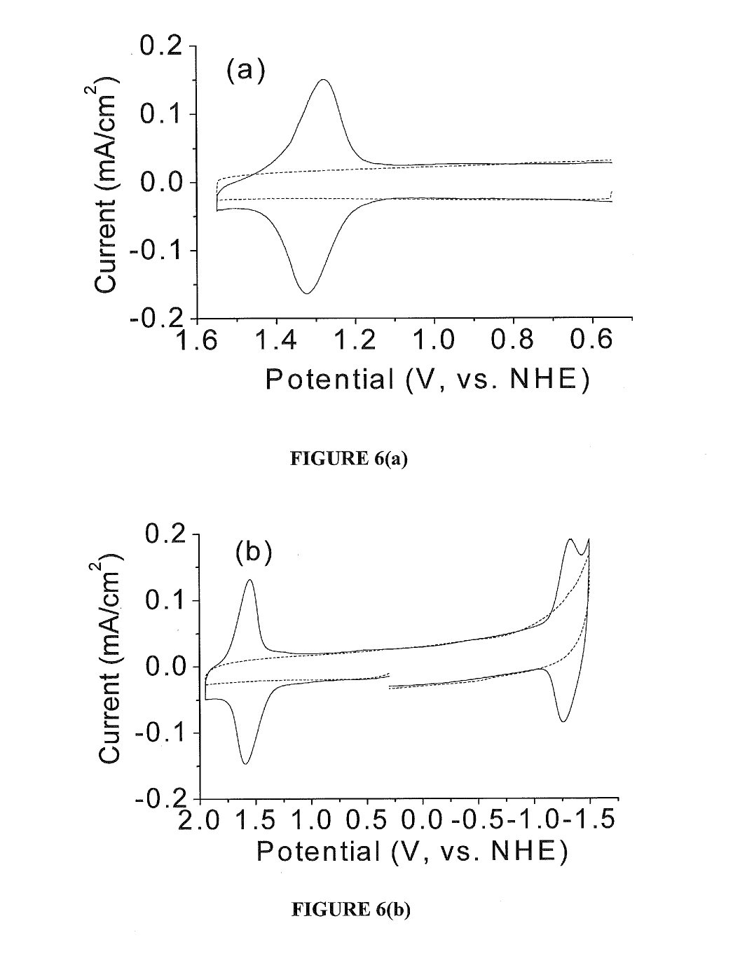

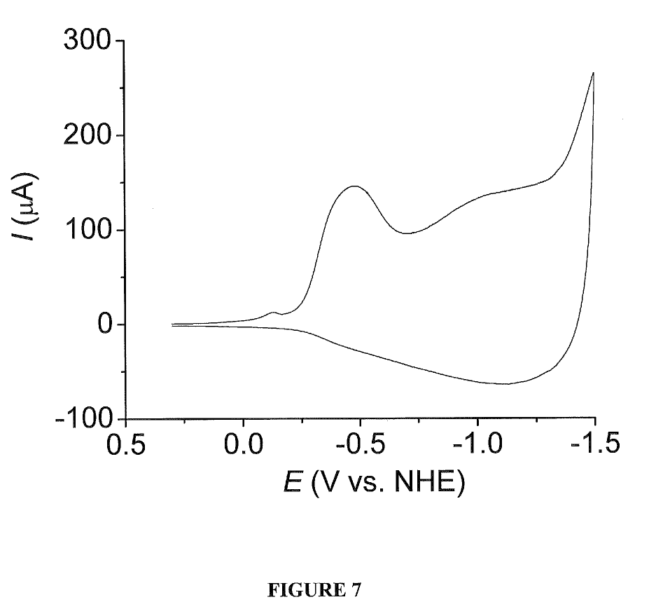

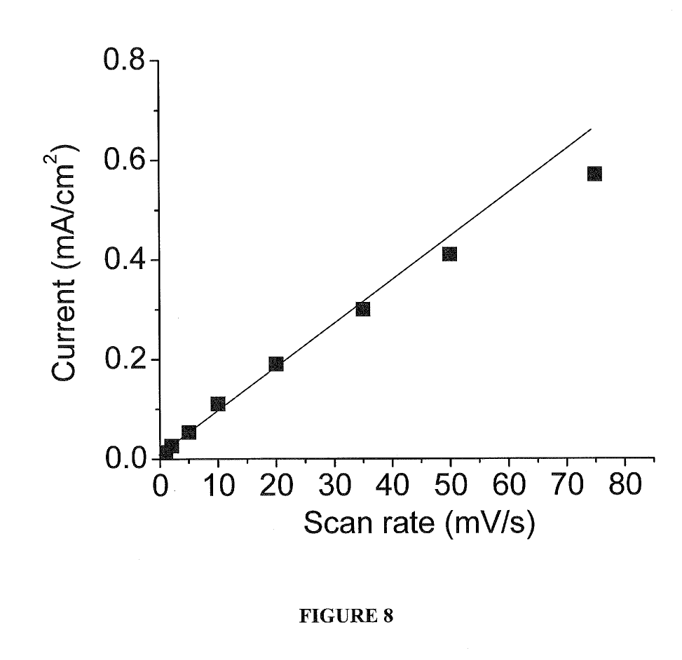

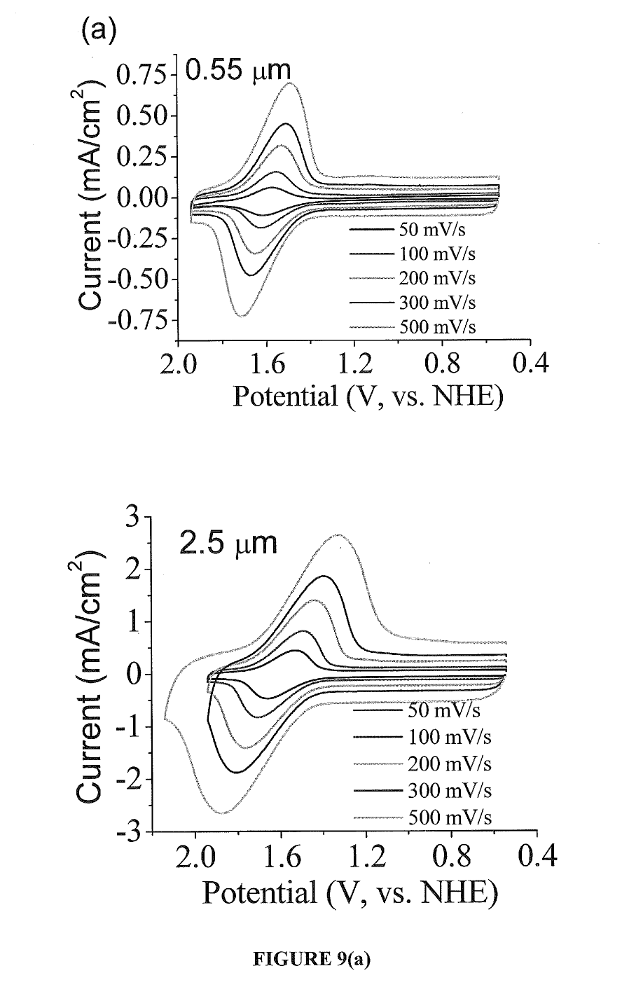

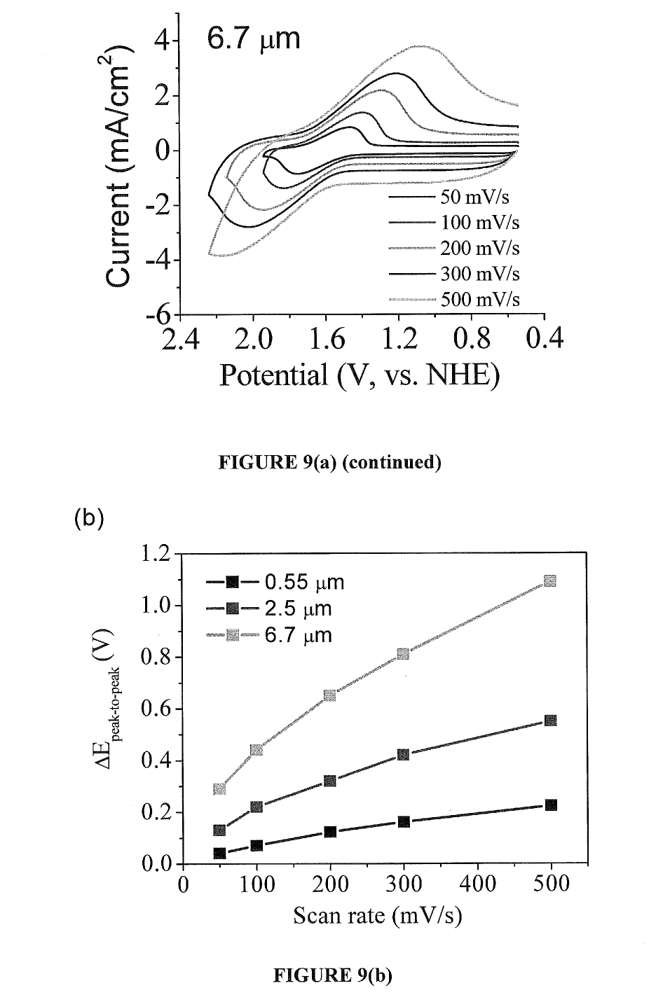

FIG. 6 shows cyclic voltammograms (CVs) for ITO|nanoITO-Ru^{II} and background scans in water and acetonitrile (MeCN). A fully reversible wave is observed for the surface-bound R^{III/II} couple, E_{1/2}(R^{III/II})=1.3 V vs. NHE in 0.1 M HClO₄/H₂O, FIG. 6a. As shown in FIG. 6b, in 0.1 MⁿBu₄NPF₆/MeCN, the R^{III/II} couple appears at 1.57 V and a reversible ITO|nanoITO-Ru^{II}(bpy)²⁺/Ru^{II}(bpy⁻)⁺ reduction wave at E_{1/2}=−1.26 V vs. NHE. As shown in FIG. 7, there is an extended reductive background compared to nanoTiO₂. For background subtracted CVs of ITO|nanoITO-Ru^{II}, peak currents (iₚ) for the Ru^{III/II} couple vary linearly with scan rate at low scan rates (≦50 in V/s) for thicknesses from 0.55-2.5 μm in both solvents and peak-to-peak splittings, (ΔEₚ=E_{p,a}−E_{p,c}) are less than 50 mV. These results are consistent with kinetically facile electron transfer to and from surface-confined redox couples, FIG. 8. At higher scan rates, the peak-to-peak splitting increases with both scan rate and thickness, FIG. 9.

Current densities greatly exceed those for the same complex on planar ITO or FTO electrodes. A current density of 125 μA/cm² (background subtracted) for a 2.5 μm nanoITO-Ru^{II} film was observed compared to 0.9 μA/cm² for planar ITO at a scan rate of 10 mV/s. This gives a surface roughness factor of 140 relative to the planar surfaces. Comparison of surface coverages from UV-visible and CV peak current measurements show that ˜90% of the adsorbed Ru^{II} sites in nanoITO-Ru^{II} are oxidized during an oxidative excursion from 0.55-1.5 V at 10 mV/s.

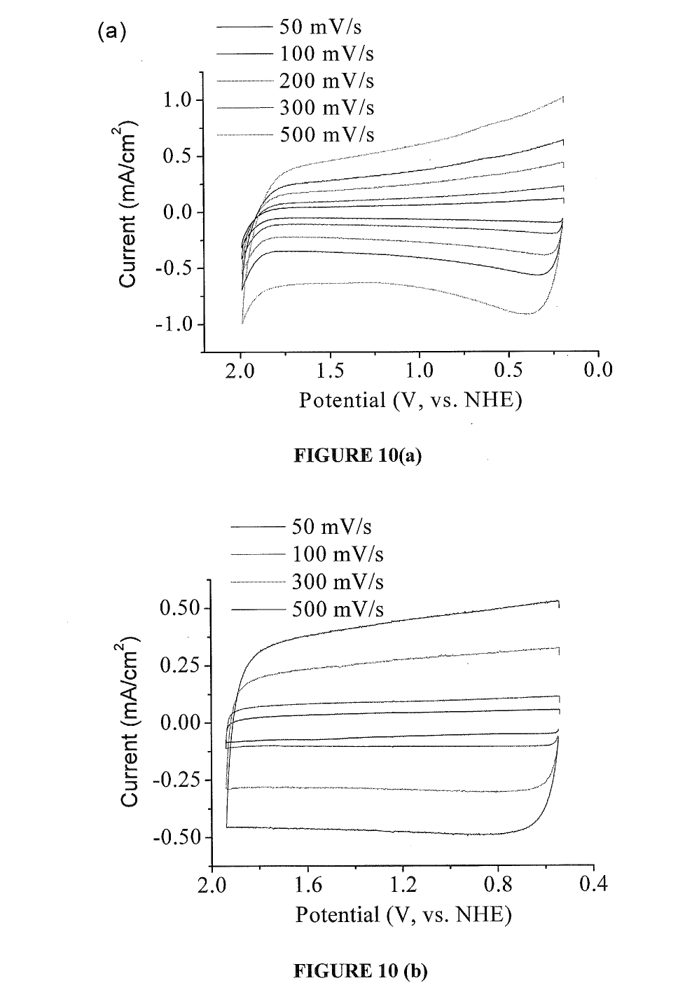

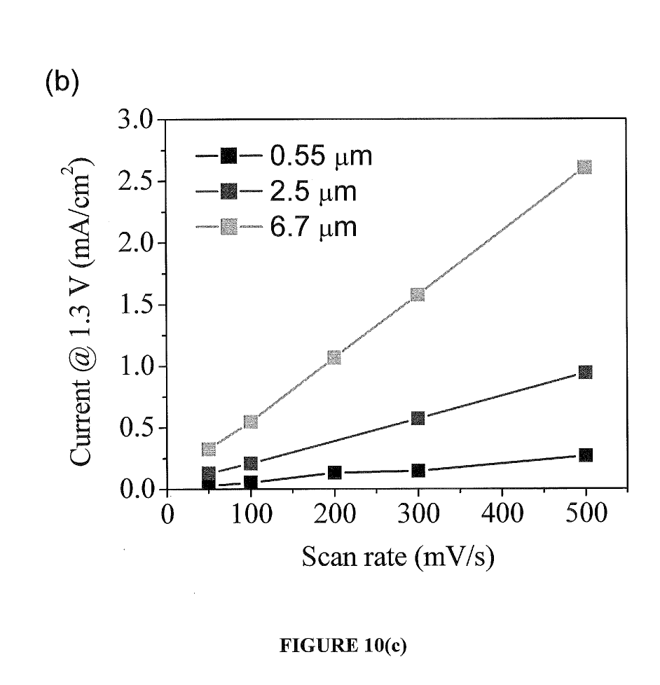

The scan rate dependence of background, non-Faradaic currents at 1.3 V were measured for underivatized films in 0.1 M HClO₄/H₂O and 0.1 M ⁿBu₄NPF₆/MeCN, FIG. 10. A linear relationship was observed between double layer charging current and scan rate at scan rates >50 mV/s in 0.1 M ⁿBu₄NPF₆/MeCN with slopes increasing from 0.5 mA·s/cm²·mV for 0.55 μm thick films to 5 mA·s/cm²·mV at 15.7 μm consistent with well-defined capacitve behavior.

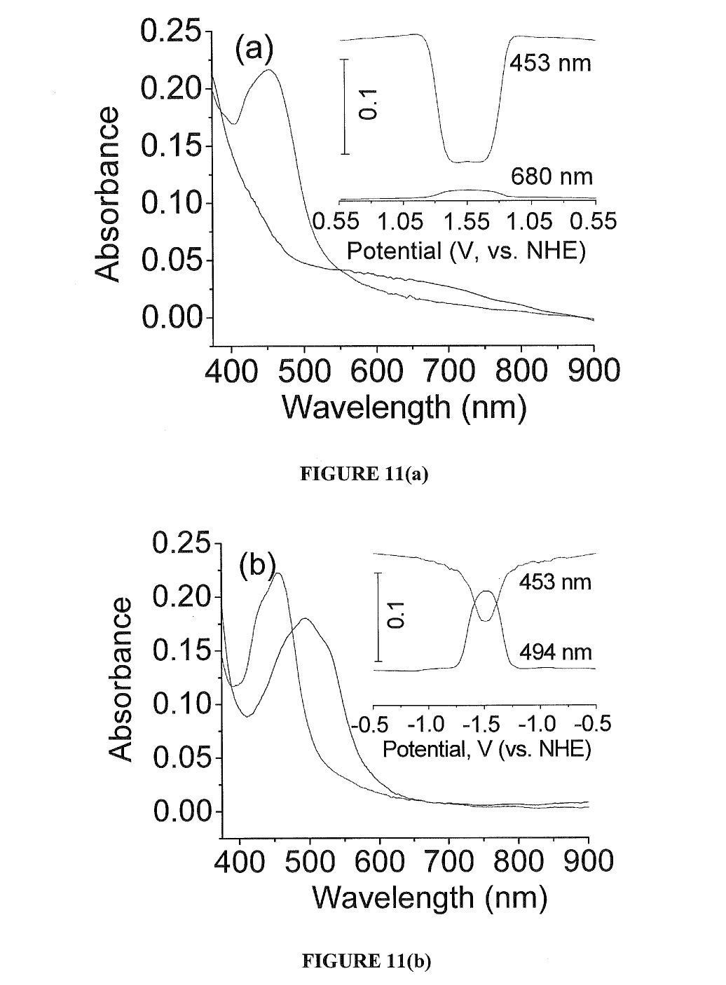

Spectroelectrochemical measurements on ITO|nanoITO-Ru^{II} demonstrate reversibility through multiple oxidative, ITO|nanoITO-Ru^{III/II}, and reductive, nanoITO-Ru^{2+/+}, cycles. As shown in FIG. 11, in aqueous 0.1 M HClO₄, this enables direct spectral (rather than current) monitoring of ITO|nanoITO-Ru^{III/II} voltammograms during an oxidative excursion from 0.55 to 1.55 V at 10 mV/s. Oxidation results in quantitative conversion of nanoITO-Ru^{II} (λₘₐₓ=453 nm) to nanoITO-Ru^{III} (λₘₐₓ=650 nm) and, as shown in the inset, is quantitatively reversible. Similarly, a reductive excursion through the nanoITO-Ru^{2+/+} wave in deaerated 0.1 M ⁿBu₄NPF₆/MeCN results in reversible reduction to nanoITO-Ru(bpy⁻)(bpy)₂⁺ (λₘₐₓ=494 nm).

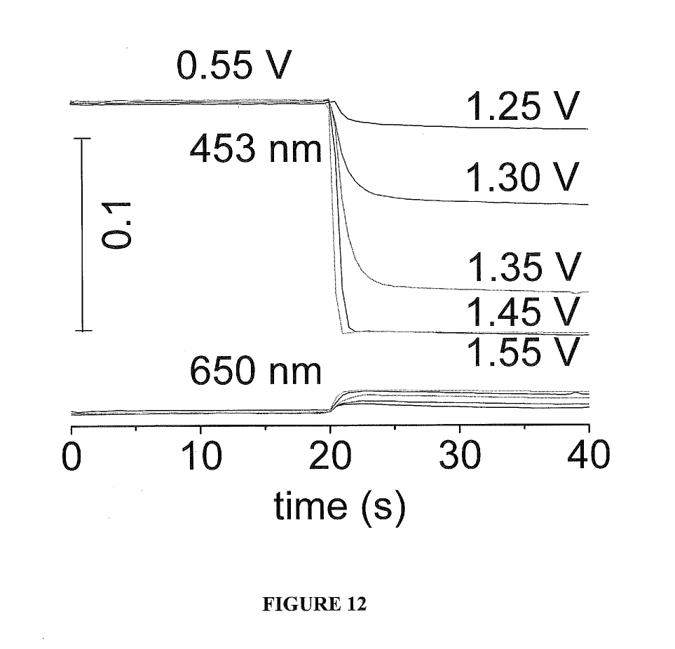

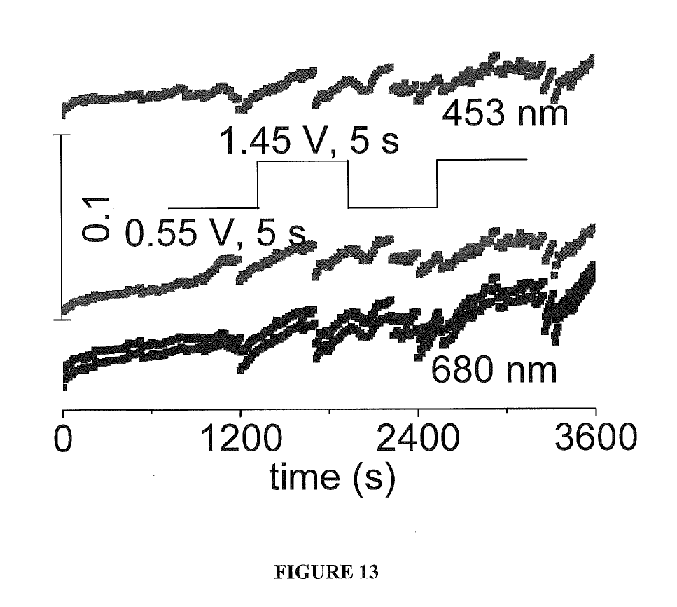

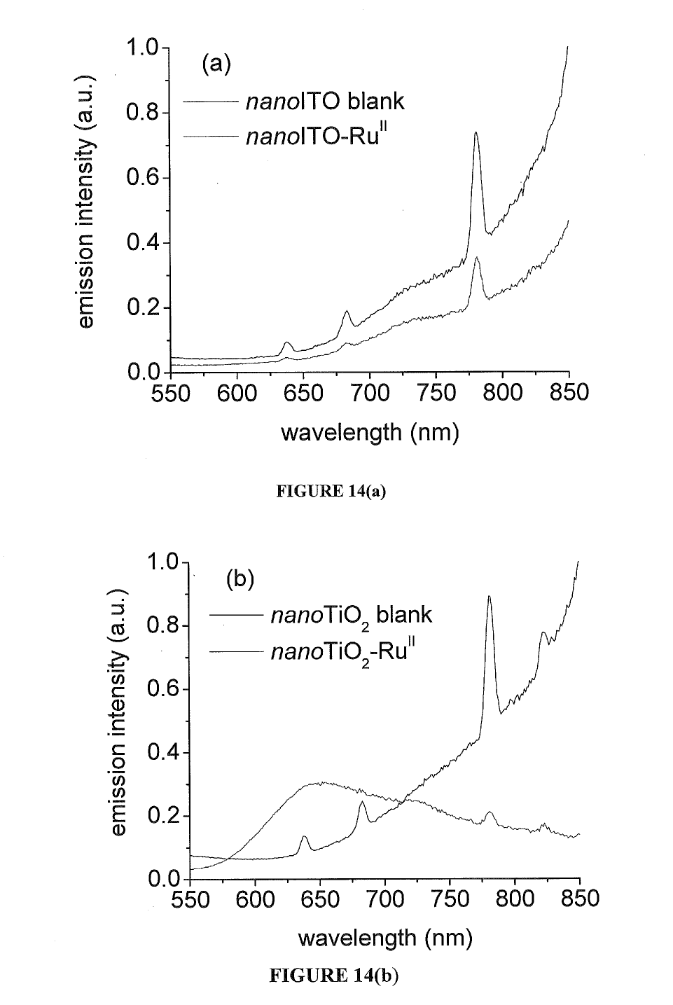

For a potential step from 0.55 V to 1.45 V vs. NEE, well past E°′ for the nanoITO-Ru^{III/II} couple, oxidation was complete in <2 s in a film of thickness 2.5 μm, FIG. 12. Stepping the potential from 1.45 to 0.55 V results in complete recovery of the original Ru^{II} spectrum. The Ru^{III/II} redox cycle was repeated 360 times without significant change, FIG. 13. There is no luminescence from nanoITO-Ru^{II} consistent with the conducting nature of nanoITO as the substrate, FIG. 14.

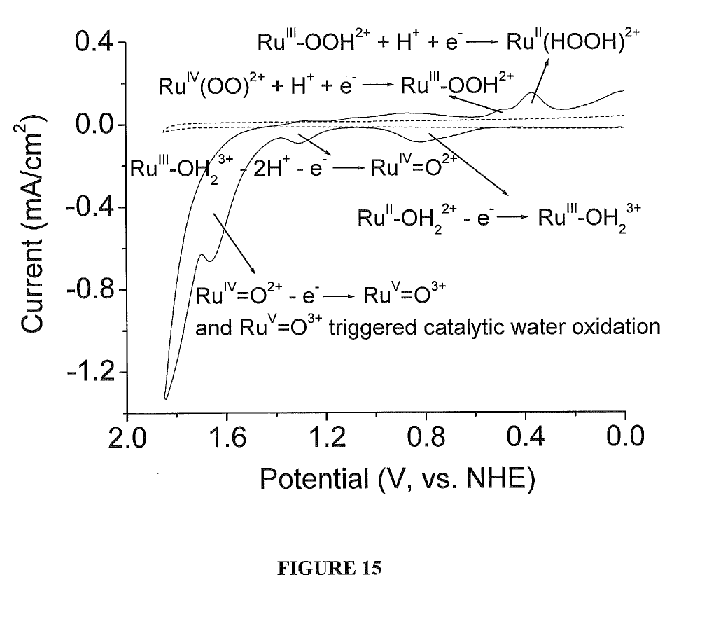

It was reported water oxidation catalysis by the single-site, surface-bound catalyst [Ru(Mebimpy)(4,4′-((HO₂OPCH₂)₂ bpy)(OH₂)]²⁺ (1-PO₃H₂) (Mebimpy is 2,6-bis(1-methylbenzimidazol-2-yl)pyridine) on ITO, FTO and FTO|nanoTiO₂ electrodes. (See Schwab et al., Inorganic Chemistry 2003, 42, 6613-6615. and Biancardoa, et al., Displays 2006, 27, 19-23.) The catalyst complex adsorbs to nanoITO with a surface binding constant of K=9×10⁴M⁻¹. In cyclic voltammograms at pH 1 (0.1 M HNO₃), FIG. 15, surface waves appear for the Ru—OH₂³⁺/Ru^{III}—OH₂²⁺, Ru^{IV}═O²⁺/Ru^{III}—OH₂²⁺, and Ru^{V}═O³⁺/Ru^{IV}═O²⁺ couples at E_{1/2}=0.81, 1.25, and 1.60 V vs. NHE respectively and the surface peroxide couples Ru^{III}—OOH²⁺/Ru^{II}(HOOH)²⁺ and Ru^{IV}(OO)²⁺/R^{III}—OOH²⁺ at E_{1/2}=0.42 and 0.52 V. The latter are observed following an oxidative scan past the Ru^{V}═O³⁺/Ru^{IV}═O²⁺ couple.

The surface-bound complex on nanoITO, ITO|nanoITO-1-PO₃H₂, is also an effective electrocatalyst for water oxidation. Following a potential step to 1.85V at pH5 (I=0.1 M, CH₃CO₂H/CH₃CO₂Na), sustained catalytic currents are observed with a turnover rate, i_{cat}/nFAΓ, of ˜0.027 s−1. In this expression, i_{cat} is the catalytic current, in the number of electrons transferred per redox event (4 e-), and A the surface area in cm². The catalytic current density observed for 2.5 μm ITO|nanoITO-1-PO₃H₂ constitutes an 11-fold enhancement relative to ITO-1-PO₃H₂ and a 12-fold/μm improvement relative to ITO|nanoTiO₂-1-PO₃H₂. On nanoITO, electrocatalytic activity was maintained for at least 8 h corresponding to ˜800 turnovers per catalyst site.

### Example IV

### Electrocatalytic Water Oxidation

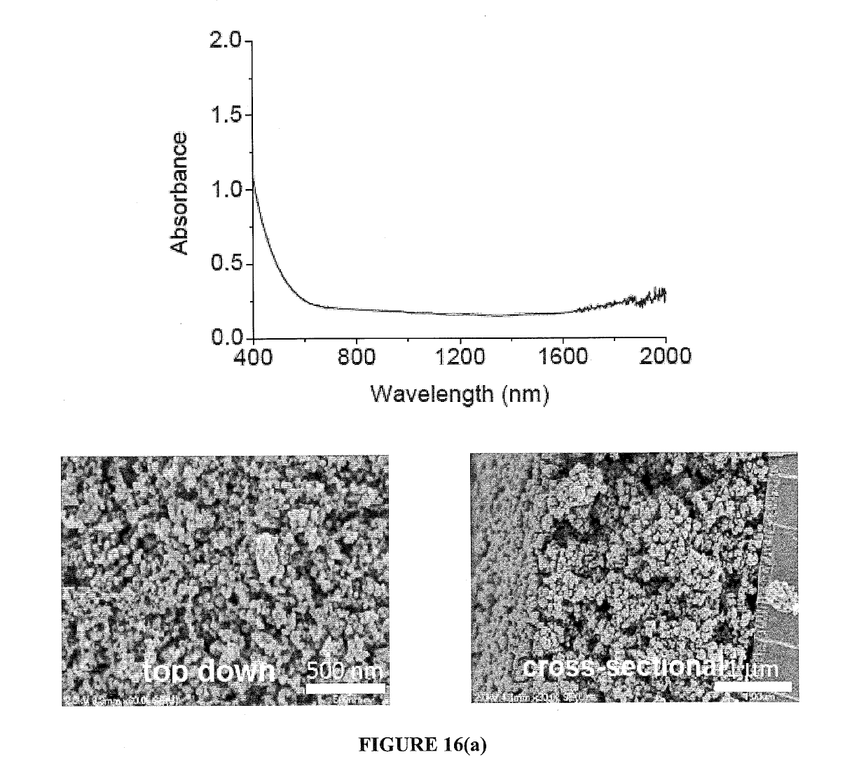

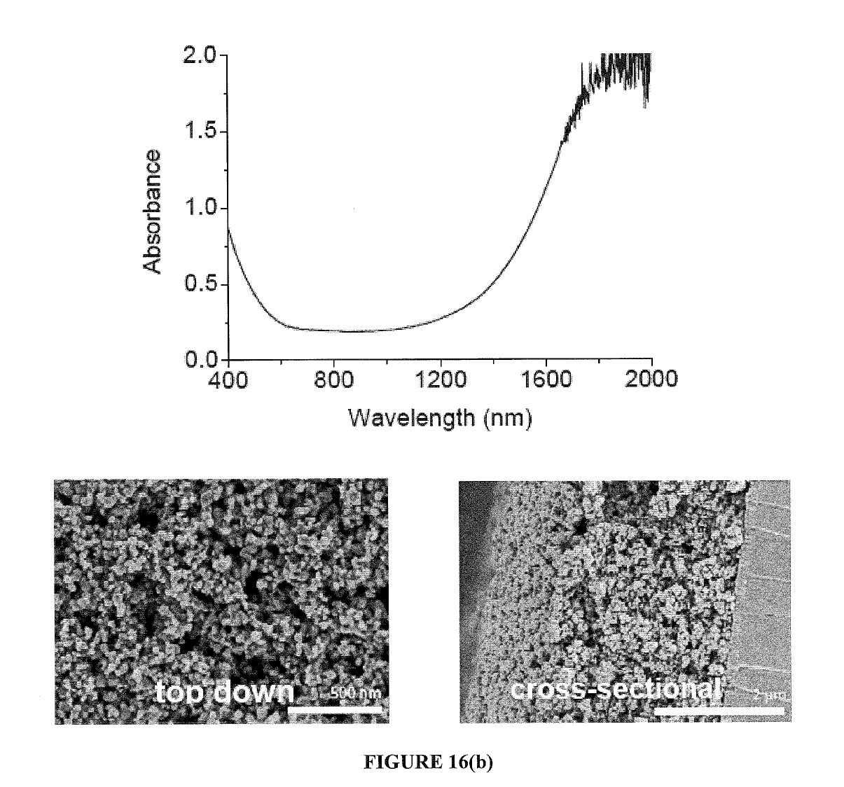

Synthesis of the water oxidation catalyst [Ru(Mebimpy)(bpy)(OH₂)]²⁺ (1) (Mebimpy is 2,6-bis(1-methylbenzimidazol-2-yl)pyridine) and its phosphonated analog [Ru(Mebimpy)(4,4′-((HO)₂OPCH₂)₂bpy)(OH₂)]²⁺ (1-PO₃H₂) has been described above. The NanoITO colloid (20-30 nm) was prepared according to procedure described above by dispersing NanoITO powder in mixed acetic acid and ethanol. It was transferred to a cleaned ITO substrate by Pasteur pipet, spun at 1000 rpm for 10 s then placed on a hot plate at 100-120° C. for several min to remove the solvent. The resulting film was annealed in a programmable tube furnace in the air at 500° C. for 1 h (oxidized, FIG. 16a) followed by an additional annealing in 3% H₂/N₂ at 300° C. for an additional hour (reduced, FIG. 16b). The resulting films are light blue and ˜2.5 μm thick with a resistance of R_{S}=˜200 Ohms across 1 can of film by a two-point probe measurement on a borosilicate glass substrate.

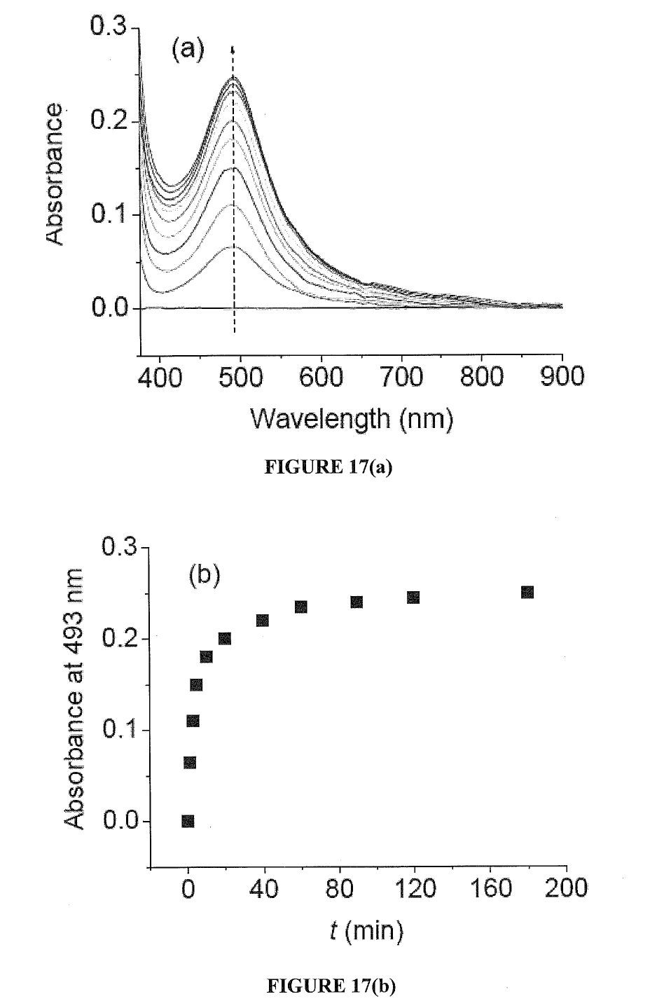

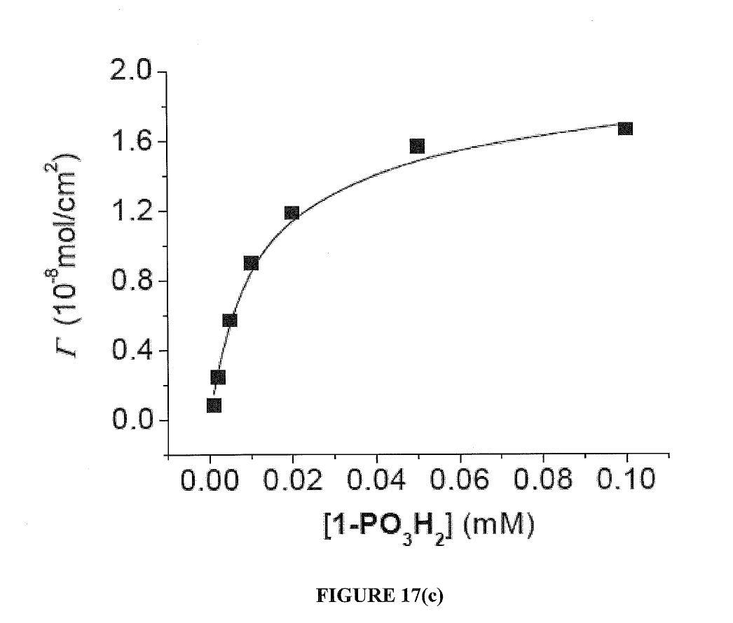

Stable phosphonate surface binding of 1-PO₃H₂ on ITO|NanoITO occurred following exposure of the slides to 0.1 mM 1-PO₃H₂ in methanol. The extent of surface loading in mol/cm² was calculated from UV-visible measurements by using Γ=A(λ)/(10³×ε(λ)), with A(λ) and ε(λ) the absorbance and molar absorptivities at λ. (See Trammell, S. A.; Meyer, T. J. J. Phys. Chem. B 1999, 103, 104.) For ITO|nanoITO|1-PO₃H₂, λₘₐₓ=493 nm with εₘₐₓ=1.5×10⁴M⁻¹cm⁻¹ for 1-PO₃H₂ in methanol were used for the surface analysis. Typical saturated surface coverage after 3 h exposure time were 1.65×10⁻⁸ mol/cm² (see FIGS. 17(a) and 17(b)). Langmuir isotherm was measured after ITO|nanoITO were placed in 0.001-0.1 mM 1-PO₃H₂ in methanol for 12 h, (see FIG. 17(c)). The equilibrium constant K=9×10⁴ M⁻¹ for surface binding were calculated from the relationship, Γ=Γₒ[M]/([M]+1/K) with Γₒ the saturated surface coverage, Γ the equilibrium coverage at a defined molar concentration, [M]. (See S. A. Trammell et al., J. Phys. Chem. B, 1999, 103, 104.)

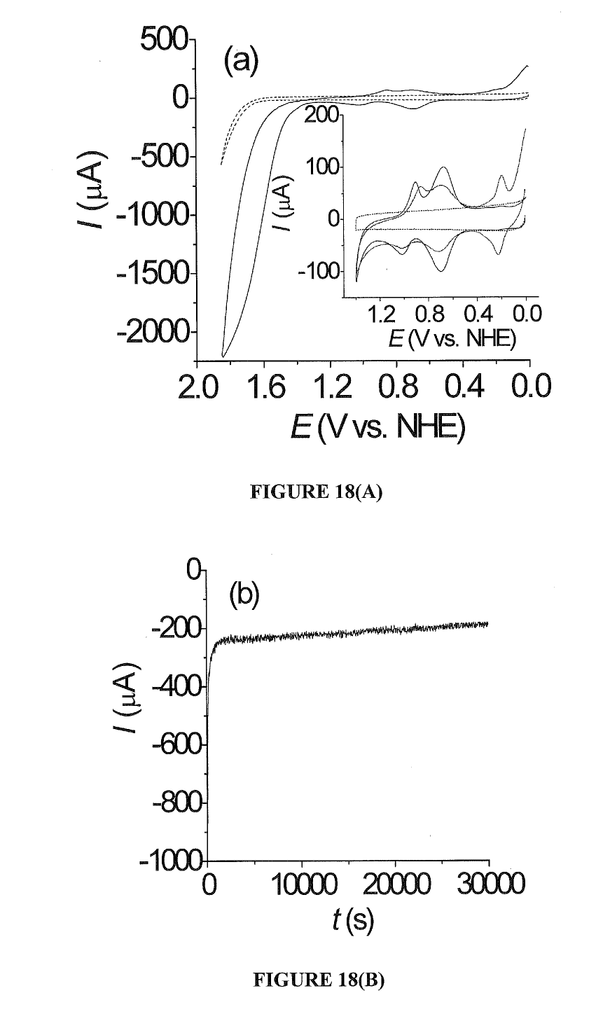

FIG. 18 (a) shows cyclic voltammogram (CV) of ITO|nanoITO|1-PO₃H₂ at pH 5(0.036 M CH₃CO₂H-0.064 M CH₂CO₂Na). FIG. 10(b) shows Electrolysis of ITO|nanoITO|1-PO₃H₂ at 1.85 V vs. NHE at pH 5. Number of turnovers≈800, turnover rate≈0.027 s⁻¹ (background subtracted). Γ=1.7×10⁻⁸ mol cm², area=1.25 cm², current density≈170 μA cm⁻² (68 μA cm⁻² μm⁻¹). In contrast to FTO|nanoTiO₂|1-PO₃H₂, where electron transfer occurs by site-to-site cross-surface hopping, charging currents before and after surface derivatization are relatively unchanged. (See Z. F. Chen, et al., J. Am. Chem. Soc., 2009, 131, 15580 and S. A. Trammell et al., J. Phys. Chem. B, 1999, 103, 104.). The pattern of waves on ITO|nanoITO|1-PO₃H₂ is similar to the pattern observed previously for [Ru(Mebimpy)(bpy)(OH₂)]²⁺ in solution at glassy carbon (GC) electrodes and for ITO|1-PO₃H. In these CVs at pH=5, a pH-dependent 1e⁻Ru(III/II) wave appears at E_{1/2}(Ru^{III}—OH²⁺/Ru^{II}—OH₂²⁺)=0.68 V vs. NHE and a well defined Ru(IV/III) wave at E_{1/2}(Ru^{IV}═O³⁺/Ru^{IV}—OH²⁺)=0.98 V. They are followed by a pH-independent wave at 1.65 V for the Ru^{V}═O³⁺/Ru^{IV}═O²⁺ couple. The latter appears at the onset of a catalytic water oxidation wave.

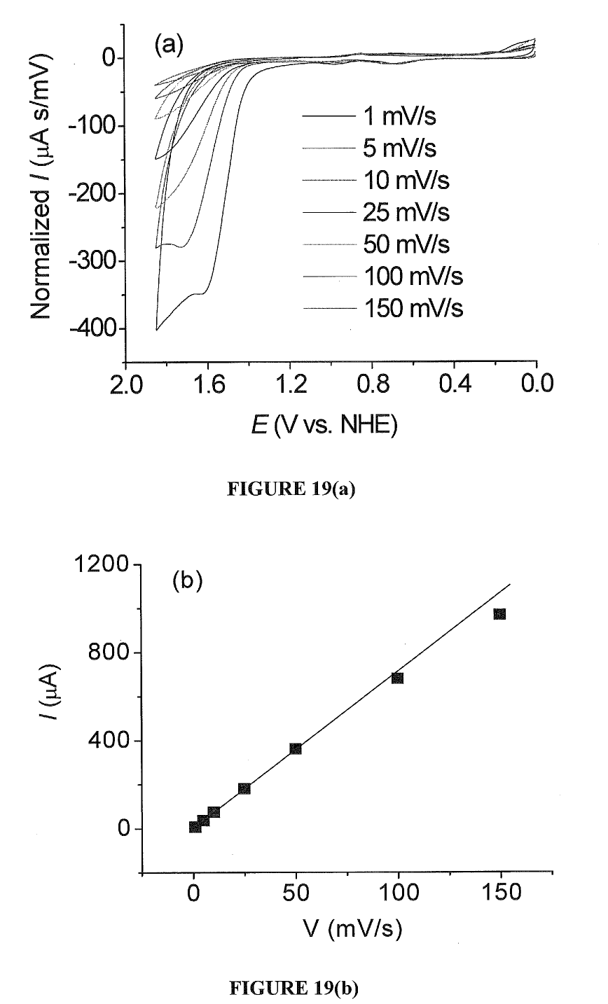

As expected for surface-bound couples, a linear relationship exists between the peak current for the Ru(III/II) couple and the scan rate from 1-100 mV/s, FIG. 19. In this range of scan rates, the peak-to-peak separation, ΔEₚ (=E_{p,a}−E_{p,c}), is ≦60 mV characteristic of rapid oxidation by electron transfer to the surface. Based on CV and UV-visible measurements, see below, 94% of the available sites are electroactive at these scan rates. At higher scan rates, ΔEₚ increases with scan rate due to the internal resistance of the nanoITO film limiting the rate of electron transfer.

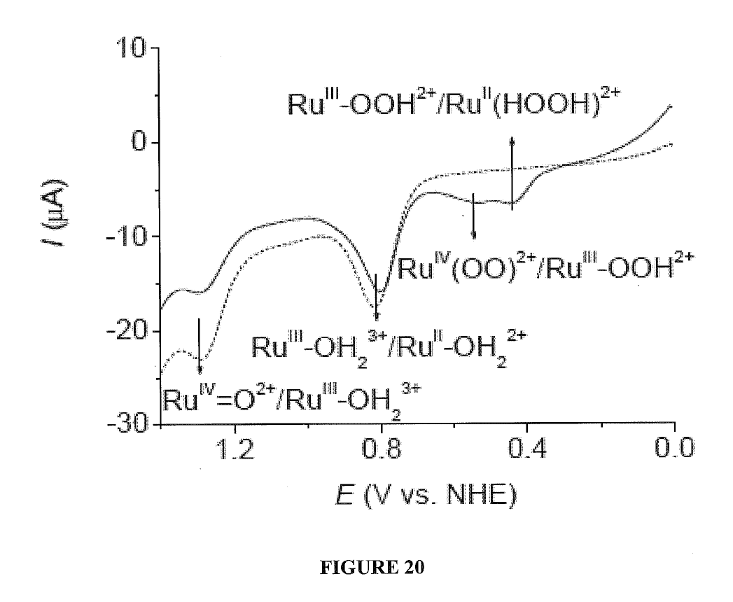

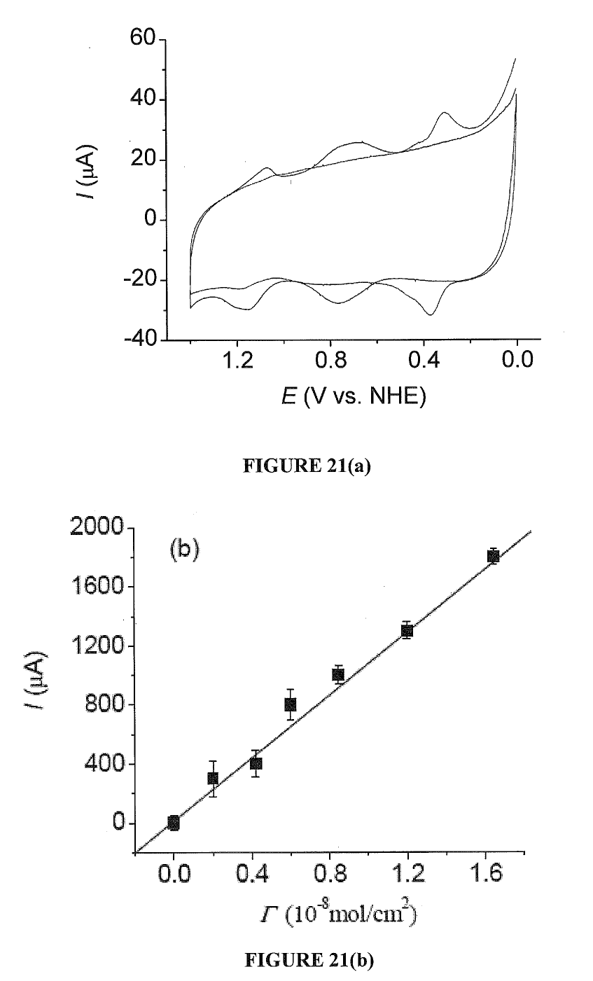

As described earlier on ITO|1-PO₃H, following an oxidative scan through the catalytic wave at E_{p,a}=1.85 V for ITO|nanoITO|1-PO₃H₂, new pH-dependent waves appear at E_{1/2}=0.31 and 0.22 V at pH 5. For both, E_{1/2} decreases with pH by ˜60 mV/pH unit from pH=1 to 8. Consistent with the pH dependence, these couples are assigned tentatively to the peroxidic couples Ru^{IV}(OO)²⁺/Ru^{III}—OOH²⁺ and Ru^{III}—OOH²⁺/Ru^{II}(HOOH)²⁺. The CV characteristics observed for the surface intermediates coincide well with solution peroxidic couples generated by controlled Ce(IV) oxidation of [Ru(Mebimpy)(bpy)(OH₂)]²⁺, FIG. 20. The long-lived peroxido intermediates are also observed at low surface coverage, e.g. Γ=1.8×10⁻⁹ mol cm⁻² (2.5 μm, 7.2×10⁻¹⁰ mol cm⁻² μm⁻¹). The absence of a surface loading dependence shows that the mechanism of formation is first order in surface catalyst, FIG. 21.

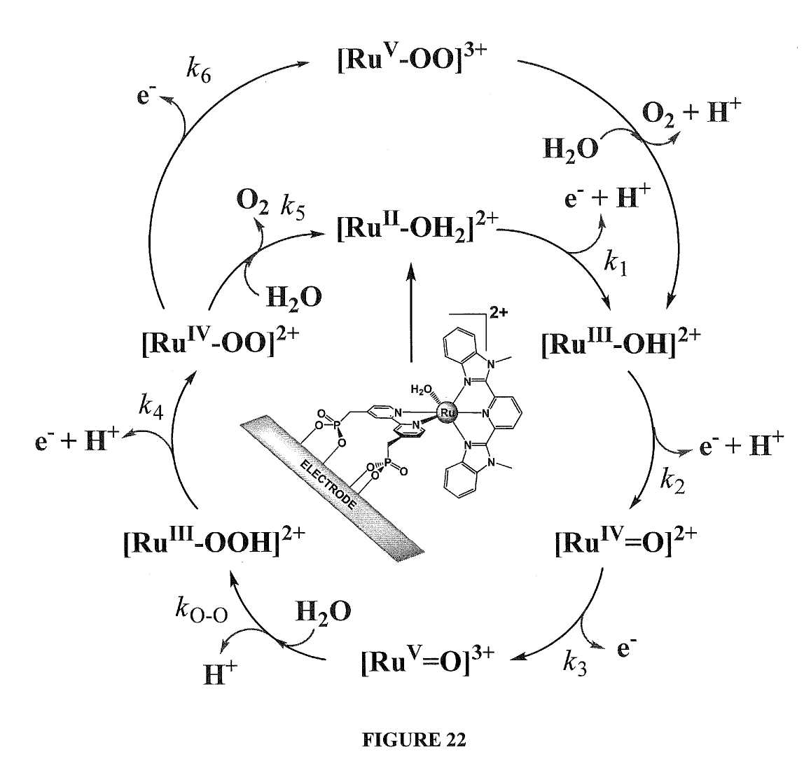

When normalized for scan rate (i_{p,a}/ν), catalytic peak currents at 1.85 V increase with decreasing scan rate consistent with a rate-limiting step prior to electron transfer to the electrode, FIG. 19. The observations reported here are consistent with the single-site mechanism in FIG. 22 with rate limiting O-atom transfer from Ru^{V}═O³⁺ to H₂O to form intermediate peroxide Ru^{III}—OOH²⁺. In the key O—O bond forming step in this mechanism, O-atom attack on H₂O by Ru^{V}═O³⁺ occurs in concert with proton transfer to a second water molecule or added base by concerted Atom-Proton Transfer (APT) pathways. Under our conditions with CH₃CO₂⁻=0.064 M, acetate dominates as the proton acceptor, eq 1 with B═CH₃CO₂⁻. (See Z. F. Chen, J. J. Concepcion, X. Q. Hu, W. T. Yang, P. G. Hoertz and T. J. Meyer, Proc. Natl. Acad. Sci. U.S.A., 2010, 107, 7225).

Stepping the applied potential to E_{p,a}=1.85 V at pH=5, results in sustained electrocatalytic water oxidation, FIG. 18(b), with a current density of ˜170 μA cm⁻² (˜68 μA cm⁻² μm⁻¹). Under these conditions the surface mechanism is as shown in FIG. 14. At this potential, initial intermediate Ru^{III}—OOH²⁺ undergoes further oxidation to Ru^{IV}(OO)²⁺ and a second oxidation to Ru^{V}(OO)³⁺ with release of O₂. Catalysis was sustained for at least 8 h corresponding to ˜800 turnovers at a turnover rate of ˜0.027 s⁻¹. Comparison of the integrated current with measured O₂ by an oxygen electrode (YSI ProODO) gave 16.2 μmol of O₂, an O₂ yield of 95%.

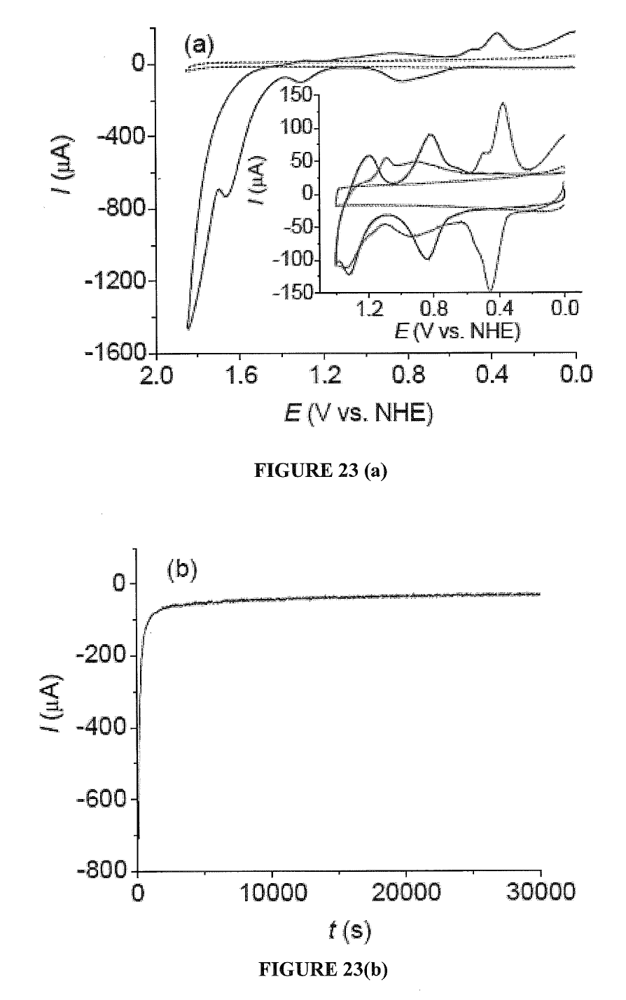

Sustained catalytic currents were also obtained at pH 1 (0.1 M HNO₃) with a current density of ˜40 μA cm⁻² (˜16 μA cm⁻² μm⁻¹), FIG. 23. The enhanced current at pH 5 is a consequence of the base effect in eq 1 with CH₃CO₂⁻ acting as the APT acceptor base. Compared to FTO|nanoTiO₂|1-PO₃H₂, the current density for water oxidation at ITO|nano|TO|1-PO₃H₂ is enhanced by ˜12-fold/km at pH 5. Compared to FTO|1-PO₃H₂, there is an increase in current density in the 2.5 μm film of ˜11-fold.

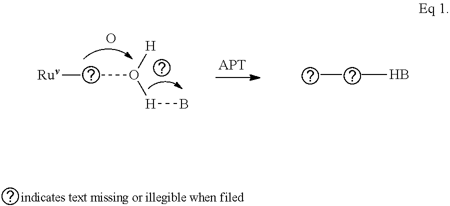

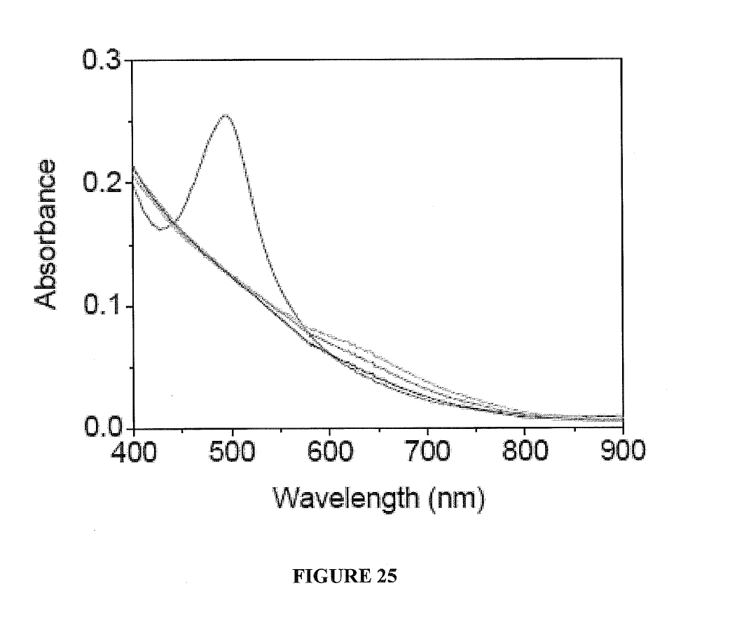

The spectral evolution of ITO|nanoITO|1-PO₃H₂ during a CV scan, FIG. 15, was monitored at pH 1 (0.1 M HNO₃), FIG. 16. Spectra obtained at a series of fixed potentials are shown in FIG. 25 and are consistent with those obtained upon oxidation of [Ru(Mebimpy)(bpy)(OH₂)]²⁺ by controlled addition of Ce(IV). (These experiments demonstrate that optically transparent nanoITO electrodes provide a basis for real time spectrophotometric monitoring of voltammograms.

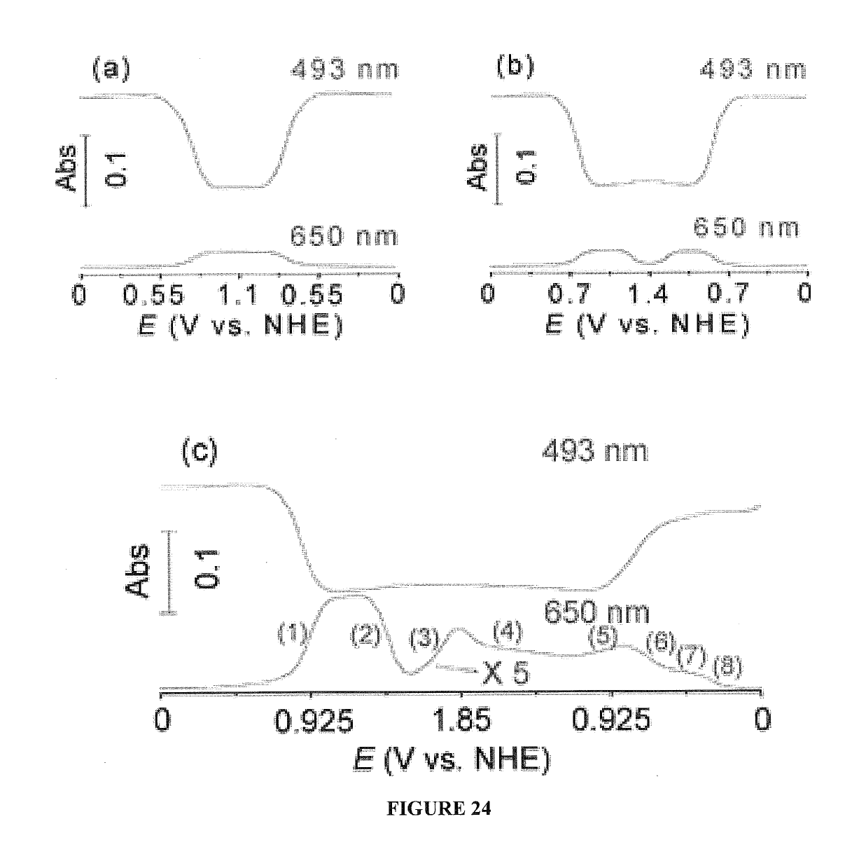

With surface potential scanning past E_{1/2}=˜0.82 V for the Ru(III/II) couple, the Metal-to-Ligand Charge Transfer (MLCT) absorption band at λₘₐₓ=493 nm, which dominates the visible spectrum, decreases rapidly consistent with oxidation of Ru^{II}—OH₂²⁺ to Ru^{III}—OH₂³⁺, FIG. 24(a). The decrease in MLCT absorption is accompanied by a simultaneous increase in the ligand-to-metal charge transfer (LMCT) absorption band for Ru^{III}—OH₂³⁺ at λₘₐₓ=650 nm. Reversal of the potential scan from 1.1 to 0 V results in complete recovery of the spectrum for Ru^{II}—OH₂²⁺.

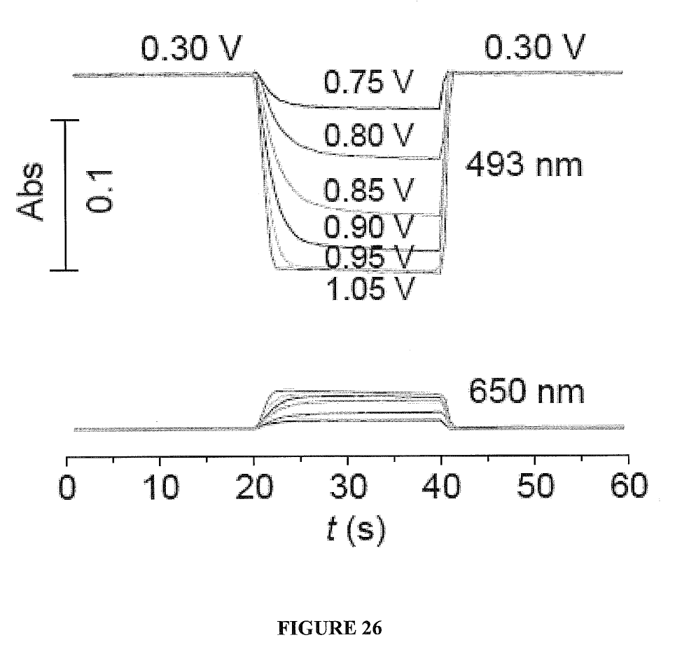

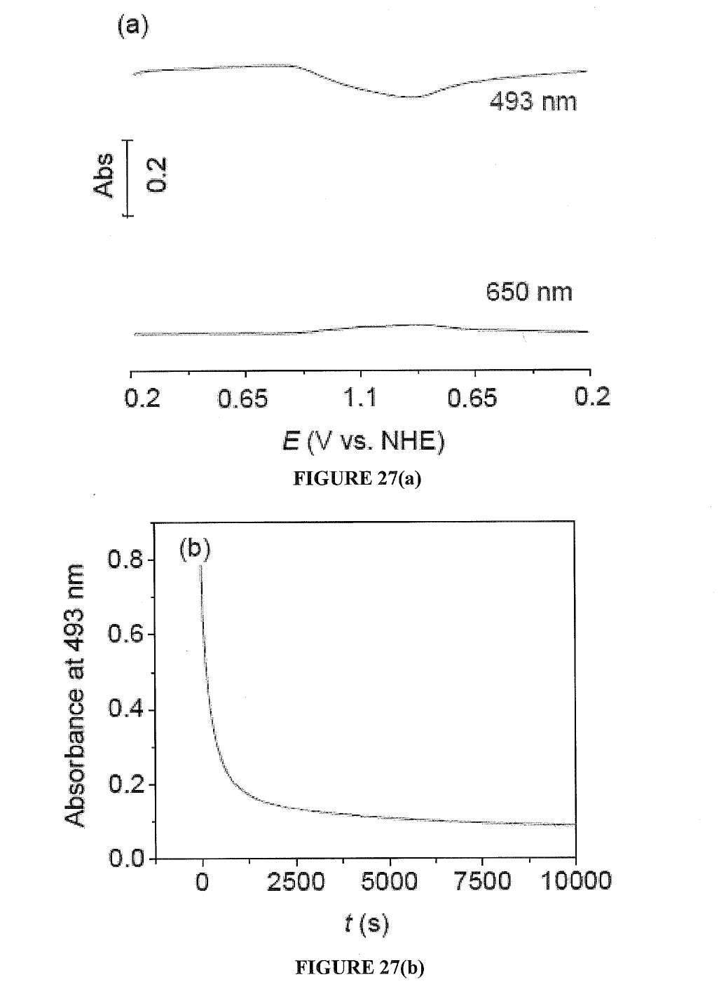

For a potential step from 0.30 V to 1.05 V vs. NHE, past the E_{1/2} for Ru^{III}—OH₂³⁺/Ru^{II}—OH₂²⁺ couple, oxidation was complete in <1.5 s, FIG. 26. This is in striking contrast to nanoTiO₂, FIG. 27, where oxidation occurs on the hours time scale and is difficult to complete.

A further increase in potential to 1.4 V, past E_{1/2} for the Ru(IV/III) couple, results in an absorption decrease at 650 nm consistent with further oxidation of Ru^{III}—OH₂³⁺ to Ru^{IV}═O²⁺, FIG. 24(b). Reversal of the potential scan from 1.4 to 0 V also results in complete recovery of the original spectrum.

A further increase in potential from 1.4-1.85 V followed by scan reversal reveals a complex series of spectral changes consistent with the sequence of reactions in FIG. 22. They are illustrated by the data in FIG. 24(c) obtained at 650 nm. These results are consistent with the sequence:

(1) Ru^{II}—OH₂²⁺-e⁻→Ru^{III}—OH₂³⁺

(2) Ru^{III}—OH₂³⁺-2H⁺-e⁻→Ru^{IV}═O²⁺

(3) Ru^{IV}═O²⁺-e⁻→Ru^{V}═O³⁺ and the following water oxidation cycle

(4) Ru^{IV}(OO)²⁺ as a stable intermediate on the surface

(5) R^{III}—OH²⁺+2H⁺+e⁻→Ru^{III}—OH₂³⁺

(6) Ru^{III}—OH₂³⁺+e⁻→Ru^{II}—OH₂²⁺

(7) Ru^{IV}(OO)²⁺+H⁺+e⁻→Ru^{III}—OOH²⁺

(8) Ru^{III}—OOH²⁺+H⁺+e⁻→Ru^{II}(HOOH)²⁺

### Example V. Electrocatalytic Oxidation of Alcohols by Ru^{V}═O and Ru^{IV}═O on nano-ITO Electrodes

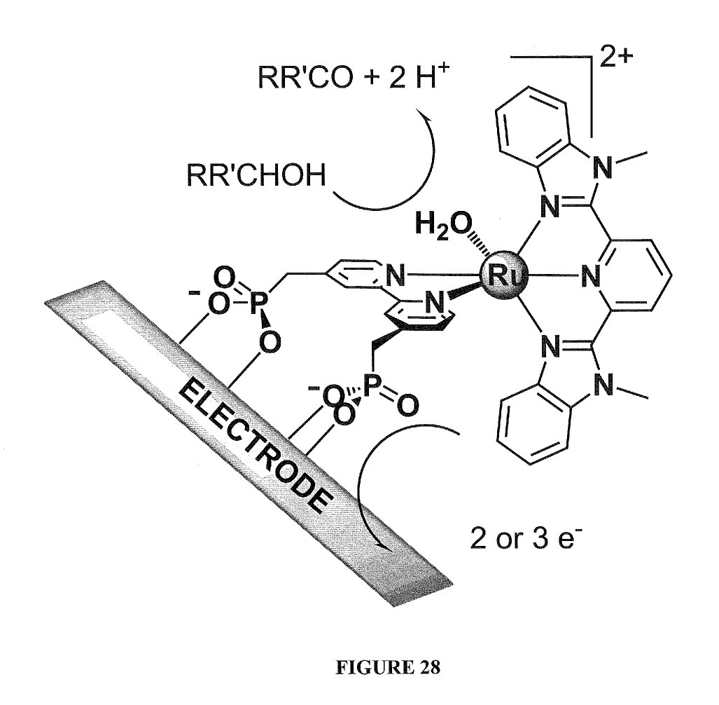

A study of interfacial electrocatalytic C—H oxidation by Ru^{V}═O³⁺, and rate comparisons with the less reactive Ru^{IV}═O²⁺ form of Ru(tpy)(bpz)(OH₂)²⁺ (tpy is 2,2′:6′,2″-terpyridine; bpz is 2,2′-bipyrazine) was carried out (FIG. 28). In addition, the surface kinetics and mechanism is monitored by high surface area nanoITO and combined optical/electrochemical measurements.

The complexes [Ru(Mebimpy)(bpy)(OH₂)]²⁺ (Mebimpy=2,6-bis(1-methylbenzimidazol-2-yl)pyridine, and bpy=2,2′ bipyridine) and [Ru(Mebimpy)(4,4′-((HO)₂OPCH₂)₂bpy)(OH₂)]²⁺ (4,4′-((HO)₂OPCH₂)₂ bpy is 4,4′-bis-methlylenephosphonato-2,2′-bipyridine) (1-PO₃H₂) have prepared according to known methods. (See Galopponi, E.; Coord. Chem. Rev. 2010, 248, 1283. and Chen, et al., J. Am. Chem. Soc. 2009, 131, 15580.) High surface area nanoITO (2.5 μm) films on ITO were prepared according to literature methods. (See Hoertz, et al., Inorg. Chem. 2010, 49, 8179.) Metal oxide surfaces were functionalized with the phosphonate-derivatized catalyst, by soaking in 0.1 mM methanol solutions of 1-PO₃H₂ for 6-12 hours resulting in complete surface coverage, Γₒ=1.2×10⁻¹⁰ mol/cm² on ITO or FTO, 1.7×10⁻⁸ mol/cm² (2.5 μm; 6.8×10⁻⁹ mol cm⁻² (area) μm⁻¹ (thickness)) on nanoITO. The Ru^{IV}═O²⁺ form of the surface-bound catalyst, nanoITO|Ru^{IV}═O²⁺, was generated by dipping nanoITO|Ru^{II}—OH₂²⁺ in solutions ˜0.1 mM in NaOCl at pH 9 for 2 sec, followed by thorough rinsing with water, and soaking in acetate buffer (pH=5, I=0.1 M) for 30 seconds.

Kapton tape was used to limit the electrode surface to 1 cm². Surface concentrations were determined by the absorbance measurements at 495 nm. Kinetic analysis was performed with SPECFIT-32. Aqueous electrolyte solutions and buffers were used to maintain ionic strength at 0.1. Aqueous acetate buffer (100 mL) at pH 5 (I=0.1 M) was prepared by mixing 1.5 M sodium acetate (66.7 mL) with 1.5 M acetic acid (27.7 mL), and adding 5.6 mL of water. Electrochemical experiments were conducted by using a BAST 100E potentiostat, with a conducting-glass|nanoITO working electrode (connected by an alligator clip), a platinum counter electrode, and a Ag/AgCl reference electrode. Scans were limited to a potential window of −0.2-1.6 V (vs. NHE). UV-Visible spectra were recorded on an Agilent 8453 spectrophotometer with a 1 cm² cuvette. Products were analyzed using two methods. Benzaldehyde was analyzed by NMR using 1,3,5 trimethoxy benzene as an internal standard. Following electrolysis, the products were extracted into dichloromethane, dried over MgSO₄, filtered, and the solvent removed in vacuo. For acetone as product, the electrolyte solution was transferred to a gas-tight screw cap vial with 2,2,2 trifluoroethanol as internal standard, and slowly heated to 80° C. After a 30 min. equilibration period, a sample from the headspace was injected into a Varian 450-GC equipped with a 220-MS column using a gas-tight syringe.

An ultimate target is oxidative activation of hydrocarbons with water as solvent, we investigated oxidation of methanol (MeOH), iso-propanol (i-PrOH) and benzyl alcohol (BzOH) by both nanoITO|Ru^{IV}═O²⁺ and nanoITO|Ru^{V}═O³⁺. The reactions of nanoITO|Ru^{IV}═O²⁺ were monitored spectrophotometrically by observing the appearance of characteristic metal-to-ligand charge transfer (MLCT) absorption bands in the visible. Oxidation by nanoITO|Ru^{V}═O³⁺ was monitored by cyclic voltammetry (CV) and controlled potential electrolysis.

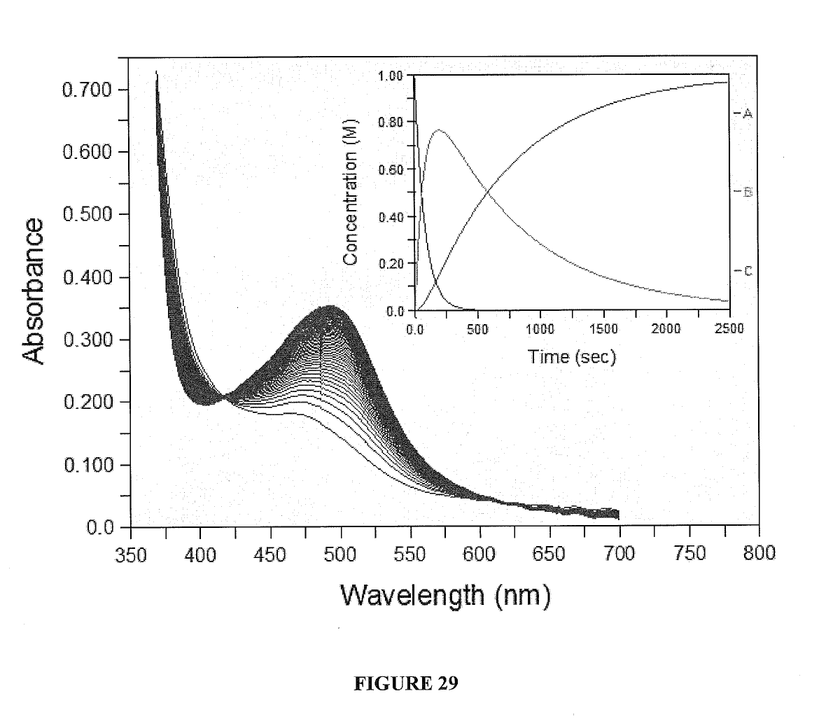

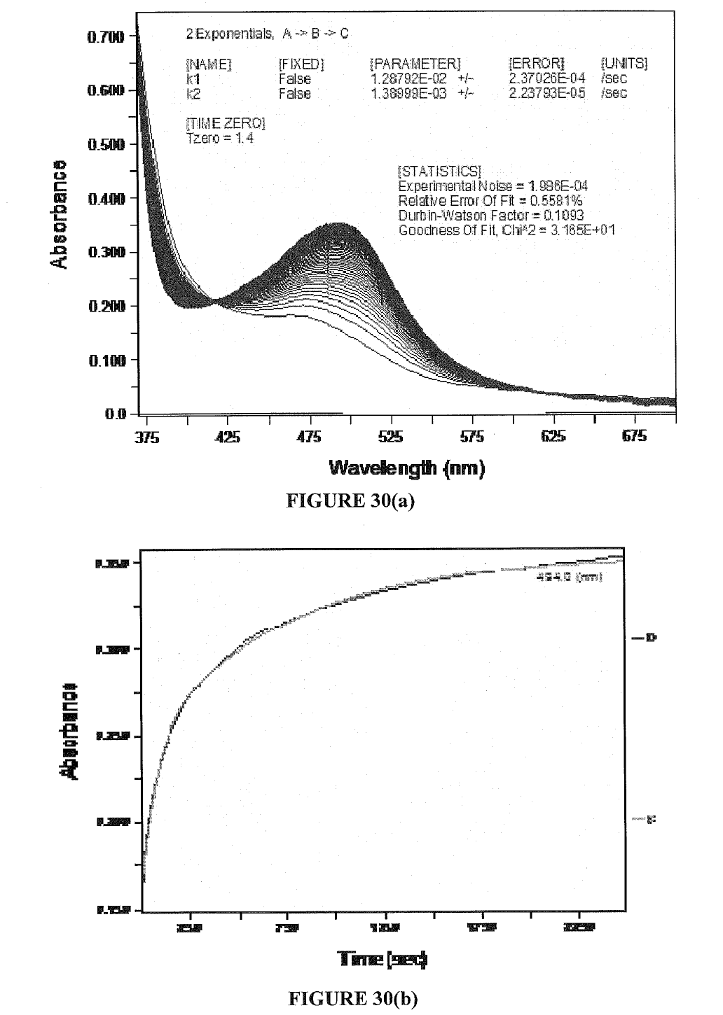

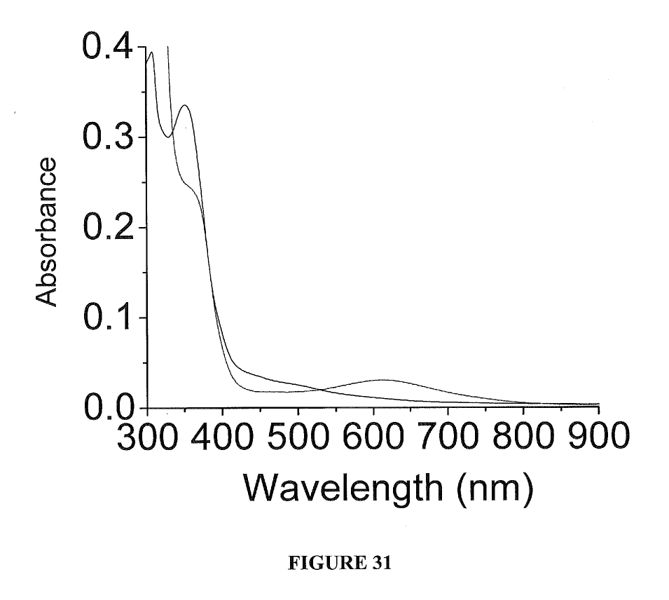

FIGS. 29 and 30 show spectral changes accompanying the addition of BzOH (46 mM in pH 5, 1=0.1 M acetate buffer at 25±2° C.) to a cuvette containing a nanoITO|Ru^{IV}═O²⁺ electrode aligned perpendicularly to the spectrometer light-path. Characteristic spectral changes for reduction to Ru(II) with λₘₐₓ=495 nm and isosbestic points at 416 and 423 nm occurred upon mixing. Importantly, there was no evidence for Ru^{III}OH²⁺ or Ru^{III}—OH₂²⁺, which have characteristic absorptions at λₘₐₓ=380 nm at pH=5, and λₘₐₓ=650 nm at pH=1 (FIG. 31), as intermediates on the surface. This suggests a concerted 2e⁻ mechanism, consistent with an earlier observation for a related oxidant. (See Galopponi, E.; Coord Chem. Rev. 2010, 248, 1283.)

The initial λₘₐₓ shifts with time to 493 nm, characteristic of surface bound Ru^{II}—OH₂²⁺, with a rate constant, kₛₒₗᵥ=1.1×10⁻³ s⁻¹, FIGS. 29 and 31. For the initial reduction to Ru(II), k_{obs} varied linearly with [BzOH] from 4-50 mM. From the slope of a plot of k_{obs} vs. [BzOH], k_{Ru(Iv)}=1.1×10⁻² M⁻¹s⁻¹ at pH=5 (I=0.1 M acetate buffer at 25±2° C.), Table 4. Total absorption changes scaled with the extent of surface coverage between Γ/Γₒ=0.4 and 1 but rates were invariant, consistent with involvement of a single surface site.

TABLE 4
Rate constants for Alcohol Oxidation by nanoITO|Ru^{IV}═O²⁺
and nanoITO|Ru^{V}═O³⁺at pH = 5 (I = 0.1M acetate
buffer at 25 ± 2° C.).

| Alcohol | k_{Ru(V)}, M⁻¹s⁻¹ | k_{Ru(IV)}, M⁻¹s⁻¹ |
|---|---|---|
| MeOH | 0.2 | <0.005 |
| i-PrOH | 36 | <0.005 |
| BzOH | 98 | 1.1 × 10⁻² |

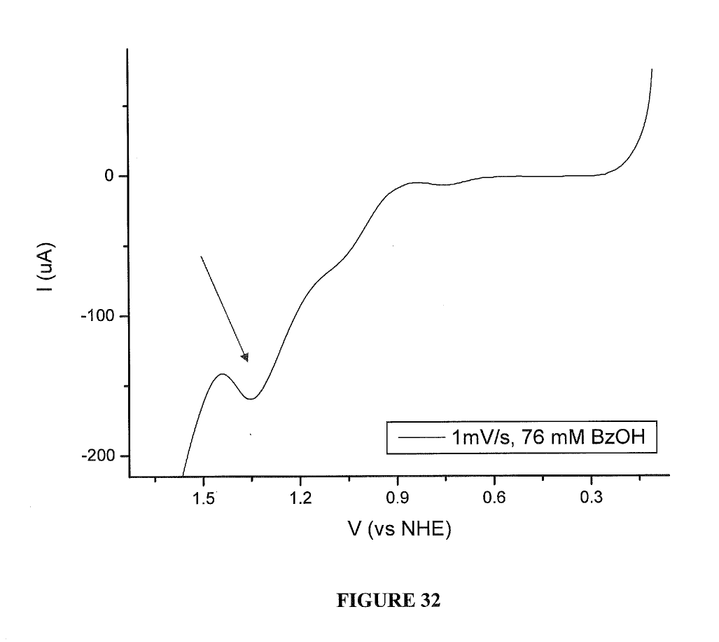

These observations are consistent with the mechanism in Equations 2a-c, with initial oxidation of BzOH occurring through a discrete Ru(II) intermediate formed by initial association and oxidation with k_{Ru(IV)}=k_{ox,Ru(IV)}K_{A}. The proposed intermediate subsequently undergoes solvolysis (kₛₒₗᵥ) to give nanoITO|Ru^{II}—OH₂²⁺. A related observation was made earlier for BzOH oxidation by the Ru^{IV}═O²⁺ oxidant [Ru^{IV}(tpy)(4,4′4(HO)₂OPCH₂)₂ bpy)(O)]²⁺ (tpy is 2,2′:6′,2″-terpyridine) on TiO₂ where the product was suggested to be the coordinated aldehyde hydrate formed by C—H insertion. Further evidence for this intermediate for 1-PO₃H₂ is provided by CV measurements and the appearance of a new Ru(III/II) wave near 1.3 V (NHE) at slow scan rates (FIG. 32).

nanoITO|Ru^{IV}═O²⁺PhCH₂OH→nanoITO|Ru^{IV}═O²⁺,PhCH₂OH:K_{A} (Eq. 2a)

nanoITO|Ru^{IV}═O²⁺PhCH₂OH→nanoITO|Ru^{II}—O(H)CH(OH)Ph²⁺:k_{ox,Ru(IV)} (Eq. 2b)

nanoITO|Ru^{II}—O(H)CH(OH)Ph²⁺+H₂O→nanoITO|Ru^{II}—OH₂²⁺+PhCHO+H₂O kₛₒₗᵥ (Eq. 2c)

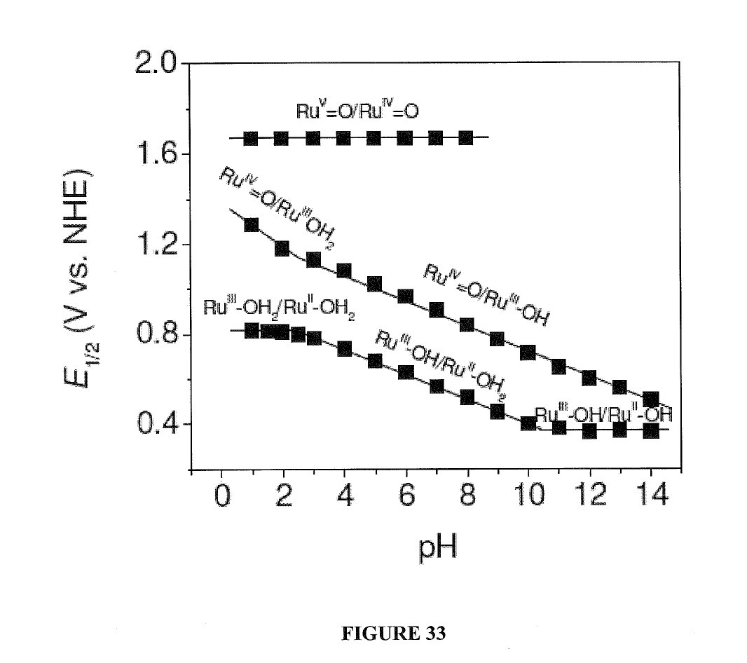

Ru^{V}═O³⁺ is a powerful oxidant in solution and on surfaces and in situ electrochemical generation provides a convenient means for studying its reactivity. (See Concepcion, et al., Acc. Chem. Res. 2009, 42, 1954 and Chen, et al., J. Am. Chem. Soc. 2009, 131, 15580.) Based on the E_{1/2}-pH diagram for the surface couples (FIG. 33), at pH=5 in acetate buffer (I=0.1, 25±2° C.), E°′ values are E°′ (nanoITO|Ru^{V}═O³⁺/Ru^{IV}═O²⁺)=1.65 V (vs. NHE) and 1.31 V for the 2e⁻ Ru^{V}═O³⁺/Ru^{III}—OH²⁺ couple. This compares with 0.98 V for the Ru^{IV}═O²⁺/Ru^{III}—OH²⁺ couple and 0.83 V for the Ru^{IV}═O²⁺/Ru^{II}—OH₂²⁺ couple. These experiments were conducted at pH 5 because of the large potential separation between the Ru^{IV}═O²⁺/Ru^{III}—OH²⁺ and Ru^{V}═O³⁺/Ru^{IV}═O²⁺ couples and because of the stability of surface binding of 1-PO₃H₂ on nanoITO at this pH.

Oxidation of all three alcohols—MeOH, i-PrOH, and BzOH—by nanoITO|Ru^{V}═O³⁺ was investigated by CV in HOAc/OAc⁻, I=0.1 M, pH=5 to ensure the absence of local pH effects at the electrode solution interface. A control experiment with LiClO₄ (0.1 M, adjusted to pH 5 with HClO₄), an inert electrolyte under these conditions, showed similar catalytic currents with no evidence for a role for added OAc⁻. In the absence of added alcohol, the peak current for the Ru(III/II) couple varies linearly with scan rate (ν) consistent with a surface bound couple:

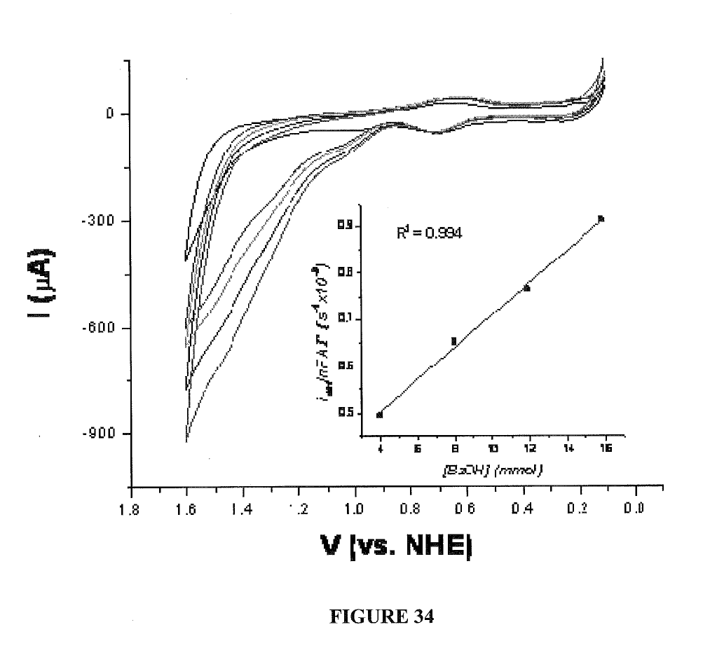

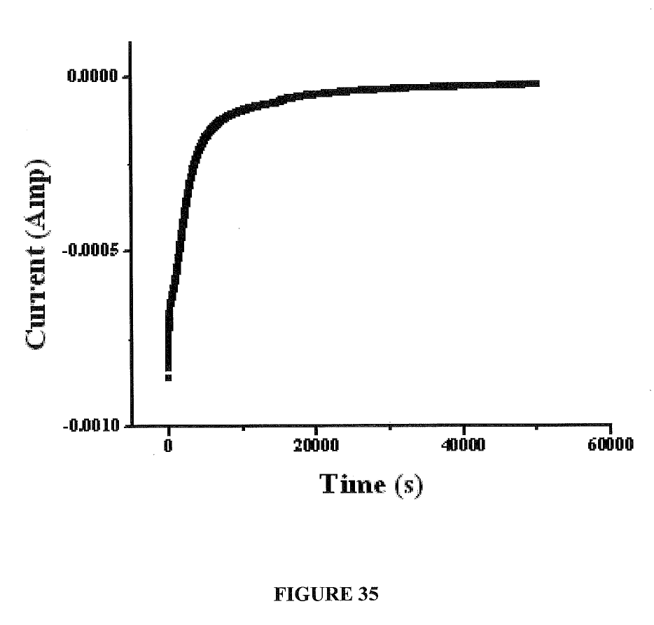

As shown in FIG. 34, oxidative scans at nanoITO|Ru^{II}—OH₂²⁺ at pH=5 in acetate buffer (I=0.1, 25±2° C.) with addition of BzOH (0-52 mM) leads to significant catalytic current enhancements. Peak current comparisons demonstrate that electrocatalysis arises from current enhancement by the Ru^{V}═O³⁺/Ru^{IV}═O²⁺ couple at E°′=1.65 V. Oxidative scans were reversed at 1.60 V because repeated scans to 1.65 V resulted in formation of nanoITO|Ru^{III}—OOH²⁺ on the surface which is a known water oxidation intermediate. Water oxidation is slower but competitive and the intermediate builds up after multiple scans.

As shown in the inset in FIG. 34, the catalytic current, i_{cat}, measured at 1.6 V, varies linearly with [BzOH]. The non-zero intercept in the plot is arises form slow background water oxidation with k=0.03 S^{-1.6} Under catalytic conditions with [BzOH]=50 mM, i_{cat} varies with ν^{1/2}, consistent with diffusional oxidation of the alcohol.

Rate constants for surface alcohol (ROH) oxidation by nanoITO|Ru^{V}═O³⁺ were evaluated by current measurements at 1.6 V at the onset for the Ru^{V}═O³⁺/Ru^{IV}═O²⁺ wave by use of eq 3. In eq 3, i_{cat} is the difference in peak currents with and without added alcohol, n is the electrochemical stoichiometry (n=2 for ROH oxidation to the corresponding aldehyde), F is the Faraday constant, A is the electrode surface area, k_{cat}(=k_{obs}) is the surface rate constant, and Γ is the surface coverage in mol/cm².

i_{cat}=nFAk_{cat}Γ (Eq. 3)

Second order rate constants, k_{Ru(V)}, were evaluated from the slopes of plots of k_{cat} vs. [Alcohol]. Alcohol and scan rate dependences for i_{cat} are consistent with the mechanism in Eq. 4 with nanoITO|Ru^{V}═O³⁺ as the oxidant and k_{Ru(V)}=k_{ox,Ru(V)}K_{A}.

nanoITO|Ru^{V}═O³⁺+PhCH₂OH→nanoITO|Ru^{V}═O³⁺,PhCH₂OH:K_{A} (Eq. 4a)

nanoITO|Ru^{V}═O³⁺,PhCH₂OH→nanoITO|Ru^{III}—OH²⁺+PhCHO+H⁺:k_{ox,Ru(V)} (Eq. 4b)

Rate constants obtained from CV measurements on nanoITO|Ru^{V}═O³⁺ oxidation of the three alcohols are listed in Table 1. Inspection of the data shows an enhancement of ˜150 for nanoITO|Ru^{V}═O³⁺ oxidation of BzOH compared to nanoITO|Ru^{IV}═O²⁺ and an enhancement of ˜490 for BzOH oxidation compared to MeOH oxidation. Reactions of nanoITO|Ru^{IV}═O²⁺ with MeOH and i-PrOH were too slow to monitor by CV due to slow background loss of the oxidant probably due to competing water oxidation.

Electrocatalytic oxidation of i-PrOH and BzOH by nanoITO-Ru^{V}═O³⁺ by controlled potential electrolysis at nanoITO|Ru^{II}OH₂²⁺ (1 cm²) at 1.6 V at pH=5 (I=0.1 M acetate buffer at 25±2° C.) was also investigated. Steady state oxidative catalytic current densities, typically between 20-30 μA/cm² for BzOH (28 in M) and iPrOH (65 mM), were reached after ˜30 min. and remained constant for ˜14 h (FIG. 33). Integrated current measurements gave 5106 and 1954 2e⁻ turnovers respectively. Product analysis for acetone from i-PrOH oxidation by Gas Chromotography and benzaldehyde from BzOH oxidation by ¹H-NMR gave 2e⁻ coulomb efficiencies of 77% for benzaldehyde (no traces of benzoic acid were visible in the ¹H NMR spectrum). A 51% coulomb efficiency was obtained for acetone, however a significant amount of the acetone product was lost by evaporation during recovery (See FIG. 34 for data and calculations).

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. An electrode comprising:
(a) a supporting substrate, and
(b) a nanoparticle composition on said substrate, said composition comprising optically transparent conductive nanoparticles.

2. The electrode of claim 1, wherein the nanoparticles comprise tin-doped indium oxide (ITO), fluorine-doped tin oxide (FTO), antimony tin oxide (ATO), gallium zinc oxide (GZO), indium zinc oxide (IZO), copper aluminum oxide, fluorine-doped zinc oxide, aluminum zinc oxide (AZO), or a combination thereof.

3. The electrode of claim 1, wherein the nanoparticles comprise tin-doped indium oxide (ITO) nanoparticles.

4. The electrode of claim 1, wherein the average diameter of the nanoparticles is less than about 80 nm.

5. (canceled)

6. The electrode of claim 1, wherein the total surface area of the electrode is about 1-10000 times more than the total surface area of an electrode made of the same material that is not in the form of nanoparticle.

7. (canceled)

8. The electrode of claim 1, wherein the nanoparticle composition is in the form of a nanoparticle coating on the supporting substrate.

9. (canceled)

10. The electrode of claim 1, wherein the supporting substrate comprises conductive material.

11. The electrode of claim 1, wherein the supporting substrate comprises at least one transparent conducting oxide (TCO).

12. (canceled)

13. The electrode of claim 1, wherein the supporting substrate comprises tin-doped indium oxide (ITO), fluorine-doped tin oxide (FTO), antimony tin oxide (ATO), gallium zinc oxide (GZO), indium zinc oxide (IZO), copper aluminum oxide, fluorine-doped zinc oxide, aluminum zinc oxide (AZO), or a combination thereof.

14. The electrode of claim 1, wherein the electrode is adapted to be used for electrolysis of water molecules or photo-electrolysis of water molecules.

15. The electrode of claim 1, further comprising a transition metal catalyst, wherein the catalyst is adsorbed to the surface of the nanoparticles.

16. The electrode of claim 15, wherein the catalyst is a ruthenium, osmium or iridium catalyst.

17. The electrode of claim 15, wherein the catalyst has a structure of formula (I): 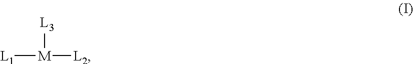
wherein M is ruthenium (Ru), osmium (Os), Iridium (Ir), Iron (Fe), Cobalt (Co), or Nickel (Ni);
L₁ is a bidentate ligand;
L₂ is a tridentate ligand; and
L₃ is a monodentate ligand.

18.-21. (canceled)

22. The electrode of claim 17, wherein the catalyst is a transition metal complex comprising at least one phosphonated derivatized ligand.

23. The electrode of claim 17, wherein the catalyst comprises at least one ligand selected from the group consisting of

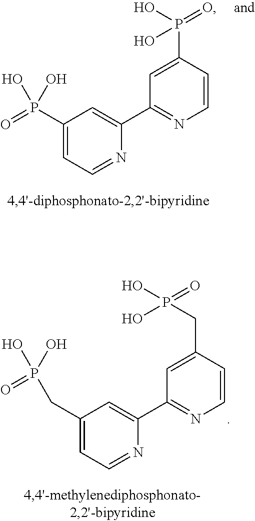 [SMILES: O=P(O)(O)c1ccnc(-c2cc(P(=O)(O)O)ccn2)c1 ; O=P(O)(O)Cc1ccnc(-c2cc(CP(=O)(O)O)ccn2)c1]

24. The electrode of claim 15, wherein the catalyst comprises [Ru(bpy)₂(4,4′-PO₃H₂-bpy)](PF₆)₂ or [Ru(Mebimpy)(4,4′-((HO)₂OPCH₂)₂bpy)(OH₂)]²⁺.

25. The electrode of claim 1, further comprising at least one dye compound, wherein the dye compound is adsorbed on the surface of the nanoparticles.

26. The electrode of claim 25, wherein the dye compound comprises at least one ligand derivatized with at least one substituent selected from the group consisting of carboxylic acid substituents, phosphonic acid substituents, silane substituents, and a combination thereof.

27. The electrode of claim 25, wherein the dye compound comprises at least one chromophore selected from the group consisting of the monomers, oligomers, and polymers of the following: porphyrins, pyrenes, perylenes, coumarins, rhodamines, buckminsterfullerenes, thiophenes, Ruthenium polypyridyl complexes, ferrocenes, methyl viologen, and combinations thereof.

28.-45. (canceled)

46. The electrode of claim 1, wherein the nanoparticle composition on the substrate has a thickness in a range of about 50-100 micron.

47.-60. (canceled)

61. The electrode of claim 1, wherein the nanoparticles comprise antimony tin oxide (ATO) nanoparticles.

62. The electrode of claim 1, wherein the electrode is adapted to be used in an electrochromic device.

63. The electrode of claim 1, wherein the electrode is adapted to be used in a real time spectrophotometric monitoring device.
